(19) United States
(12) Patent Application Publication
(10) Pub. No.: US 2025/0107275 A1
(43) Pub. Date: Mar. 27, 2025

(54) METHOD OF TRANSFERRING LIGHT EMITTING ELEMENT USING STRETCHING DEVICE

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/668,614

(22) Filed: May 20, 2024

(30) Foreign Application Priority Data
Sep. 22, 2023 (KR) 10-2023-0126732

(51) Int. Cl. H01L 33/00; H01L 25/16

(52) U.S. Cl. CPC H10H 20/018; H01L 25/167

(57) ABSTRACT

A method of transferring a plurality of light emitting elements using a stretching device includes stretching a transfer film disposed on a support portion of the stretching device by a stretching portion, and arranging the plurality of light emitting elements at a first gap on the transfer film. The method further includes reducing an elongation of the transfer film so that the stretching portion disposes the plurality of light emitting elements at a second gap narrower than the first gap, and transferring the plurality of light emitting elements disposed at the second gap on the transfer film to a substrate.

### CROSS-REFERENCE TO RELATED APPLICATION(S)

This application claims priority to and benefits of Korean Patent Application No. 10-2023-0126732 under 35 U.S.C. § 119, filed on Sep. 22, 2023 in the Korean Intellectual Property Office, the entire disclosure of which is incorporated herein by reference.

### BACKGROUND

### 1. Technical Field

This disclosure relates to a method of transferring a light emitting element using a stretching device.

### 2. Description of the Related Art

Display devices are becoming increasingly important with the development of multimedia. In response to this, various types of display devices, such as organic light emitting displays (OLED) and liquid crystal displays (LCD), are being used.

A device for displaying an image of a display device includes a display panel such as a light emitting display panel or a liquid crystal display panel. Among them, the light emitting display panel may include a light emitting diode (LED), which includes an organic light emitting diode using an organic material as a fluorescent material, or an inorganic light emitting diode using an inorganic material as a fluorescent material.

In the manufacture of a display panel utilizing inorganic light emitting diodes as light emitting elements, the spacing of the light emitting elements may be adjusted by depositing the wafer-grown Micro LEDs onto a transfer film prior to placing the wafer-grown Micro LEDs on the substrate of the display panel.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects and features of embodiments of the disclosure provide a method for reducing positional errors in case of moving a light emitting element to a target substrate by a laser-induced forward transfer (LIFT) process.

However, aspects and features of the disclosure are not restricted to those set forth herein. The above and other aspects and features of the disclosure will become more apparent to one of ordinary skill in the art to which the disclosure pertains by referencing the detailed description of the disclosure given below.

According to an aspect of the disclosure, a method of transferring a plurality of light emitting elements using a stretching device may include stretching a transfer film disposed on a support portion of the stretching device by a stretching portion, disposing the plurality of light emitting elements at a first gap on the transfer film, reducing an elongation of the transfer film so that the stretching portion disposes the plurality of light emitting elements at a second gap narrower than the first gap, and transferring the plurality of light emitting elements disposed at the second gap on the transfer film to a substrate.

According to an aspect of the disclosure, the disposing of the plurality of light emitting elements at the first gap on the transfer film may include disposing a first light emitting element emitting light of a first wavelength on the transfer film, disposing a second light emitting element emitting light of a second wavelength on the transfer film, and disposing a third light emitting element emitting light of a third wavelength on the transfer film.

According to an aspect of the disclosure, the disposing of the plurality of light emitting elements at the first gap on the transfer film may include moving the plurality of light emitting elements from a donor substrate to the transfer film by a laser-induced forward transfer (LIFT) process.

According to an aspect of the disclosure, the stretching of the transfer film disposed on the support portion may include moving a film fixing portion in a direction to place a height of the film fixing portion lower than a height of a top surface of the support portion after fixing an outer periphery of the transfer film by the film fixing portion of the stretching portion.

According to an aspect of the disclosure, the reducing of the elongation of the transfer film so that the stretching portion disposes the plurality of light emitting elements at the second gap narrower than the first gap may include the stretching portion moving the film fixing portion in the direction to reduce a difference between a height of the film fixing portion and a height of the top surface of the support portion.

According to an aspect of the disclosure, the transferring of the plurality of light emitting elements disposed at the second gap on the transfer film to the substrate may include disposing the substrate on the transfer film on which the plurality of light emitting elements disposed at the second gap are disposed, contacting the substrate with upper portions of the plurality of light emitting elements and irradiating a laser from a lower portion of the support portion to the transfer film.

According to an aspect of the disclosure, the support portion may have an opening in a center, and a laser transmitting member may be disposed in the opening. The method may further include irradiating a laser from a lower portion of the support portion to the transfer film, and irradiating the laser to melt a connection electrode disposed on a top surface of the plurality of light emitting elements and adhering the plurality of light emitting elements to the substrate.

According to an aspect of the disclosure, the irradiating of the laser from the lower portion of the support portion to the transfer film may include confirming an alignment of the plurality of light emitting elements and the substrate by an image captured by a vision member disposed at a lower end of the support portion and photographing the plurality of light emitting elements.

According to an aspect of the disclosure, the transferring of the plurality of light emitting elements disposed at the second gap on the transfer film to the substrate may include disposing a transfer head on the transfer film on which the plurality of light emitting elements disposed at the second gap are disposed, moving the transfer head to adhere the plurality of light emitting elements to a stamp of the transfer head, moving the transfer head to place the plurality of light emitting elements adhered to the stamp on the substrate, and melting bonding a connection electrode disposed at an end of the plurality of light emitting elements to the substrate.

According to an aspect of the disclosure, the moving of the transfer head to adhere the plurality of light emitting elements to the stamp of the transfer head may include attaching a viscous member disposed on a side of the stamp to the plurality of light emitting elements.

According to an aspect of the disclosure, the plurality of light emitting elements may be at least one of vertical light emitting elements or flip-chip light emitting elements.

According to an aspect of the disclosure, a method of transferring light emitting elements using a stretching device may include disposing the plurality of light emitting elements at a first gap on a transfer film that is stretched, disposing a stretching portion to space the plurality of light emitting elements at a second gap narrower than the first gap, disposing a substrate on the transfer film on which the plurality of light emitting elements at the second gap are disposed, contacting the substrate with a top surface of the plurality of light emitting elements, bonding the plurality of light emitting elements to the substrate by irradiating a laser from a bottom surface of the transfer film toward the plurality of light emitting elements and separating the transfer film and the plurality of light emitting elements.

According to an aspect of the disclosure, the method may further include, before disposing the plurality of light emitting elements at the first gap on the transfer film that is stretched, disposing the transfer film on a support, and moving the stretching portion of the stretching device in a direction to stretch the transfer film disposed on a support portion.

According to an aspect of the disclosure, the support portion may have an opening in a center, and a laser transmitting member may be disposed in the opening. The method may further include bonding the plurality of light emitting elements to the substrate by irradiating the laser from a lower portion of the support portion to the transfer film and separating the transfer film and the plurality of light emitting elements, and irradiating the laser to melt a connection electrode disposed on the top surface of the light emitting elements and adhering the plurality of light emitting elements to the substrate.

According to an aspect of the disclosure, the disposing of the plurality of light emitting elements at the first gap on the transfer film that is stretched may include disposing a first light emitting element emitting light of a first wavelength on the transfer film, disposing a second light emitting element emitting light of a second wavelength on the transfer film, and disposing a second light emitting element emitting light of a third wavelength on the transfer film.

According to an aspect of the disclosure, the disposing of the plurality of light emitting elements at the first gap on the transfer film may include moving the plurality of light emitting elements from a donor substrate to the transfer film by a laser-induced forward transfer (LIFT) process.

According to an aspect of the disclosure, the stretching portion may include a fixing frame having a circular or polygonal panel or frame structure with a circular or polygonal opening, and a film fixing portion including the fixing frame and a lower fixing portion disposed below an upper and lower driving portion.

According to an aspect of the disclosure, the moving of the stretching portion of the stretching device in the direction to stretch the transfer film disposed on the support portion may include fixing an outer periphery of the transfer film by the film fixing portion and disposing a height of the film fixing portion to be lower than a height of a top surface of the support portion.

According to an aspect of the disclosure, the bonding of the plurality of light emitting elements to the substrate by irradiating the laser from the lower portion of the support portion to the transfer film may include confirming an alignment of a plurality of light emitting elements and the substrate by an image captured by a vision member disposed at a lower end of the support portion and photographing the plurality of light emitting elements.

According to an aspect of the disclosure, the plurality of light emitting elements may be at least one of vertical light emitting elements or flip-chip light emitting elements.

According to embodiments of the disclosure, by overstretching a transfer film using a transfer film stretching device, placing light emitting elements, and reducing the degree of stretching, the position error of the light emitting element that may occur during the LIFT process may be reduced.

However, aspects and features of the disclosure are not limited to the aforementioned aspects and features, and various other aspects and features are included in the specification.

### BRIEF DESCRIPTION OF THE DRAWINGS

FIG. 1 is a schematic plan view of a display device according to an embodiment.

FIG. 2 is a schematic diagram illustrating an example of a pixel of FIG. 1.

FIG. 3 is a schematic diagram illustrating another example of a pixel of FIG. 1.

FIG. 4 is a schematic cross-sectional view illustrating a display device according to an embodiment.

FIG. 5 is a schematic cross-sectional view illustrating a pixel electrode and a light emitting element according to an embodiment.

FIG. 6 is a schematic cross-sectional view illustrating a display device according to another embodiment.

FIG. 7 is a schematic perspective view of a transfer film stretching device according to an embodiment of the disclosure.

FIG. 8 is a schematic diagram illustrating the structure of a transfer film stretching device according to an embodiment of the disclosure.

FIG. 9 is a schematic side view illustrating the structure of a transfer film according to an embodiment of the disclosure.

FIGS. 10 to 14, FIG. 17, FIG. 19, and FIG. 20 are schematic diagrams illustrating the operation of a transfer film stretching device according to an embodiment of the disclosure.

FIGS. 15 and 18 are schematic plan views of a transfer film and a fixing frame according to an embodiment of the disclosure.

FIG. 16 is a schematic diagram illustrating a laser-induced forward transfer (LIFT) process.

FIG. 21 is a schematic diagram illustrating the structure of a transfer film stretching device according to another embodiment of the disclosure.

FIGS. 22 to 25 are schematic diagrams illustrating the operation of a transfer film stretching device according to another embodiment of the disclosure.

FIGS. 26 and 27 are schematic diagrams illustrating a method of placing light emitting elements on a substrate using a transfer head according to an embodiment of the disclosure.

### DETAILED DESCRIPTION OF THE EMBODIMENTS

Embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to more clearly describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “a schematic plan view” means when an object portion is viewed from above, and the phrase “a schematic cross-sectional view” means when a schematic cross-section taken by vertically cutting an object portion is viewed from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

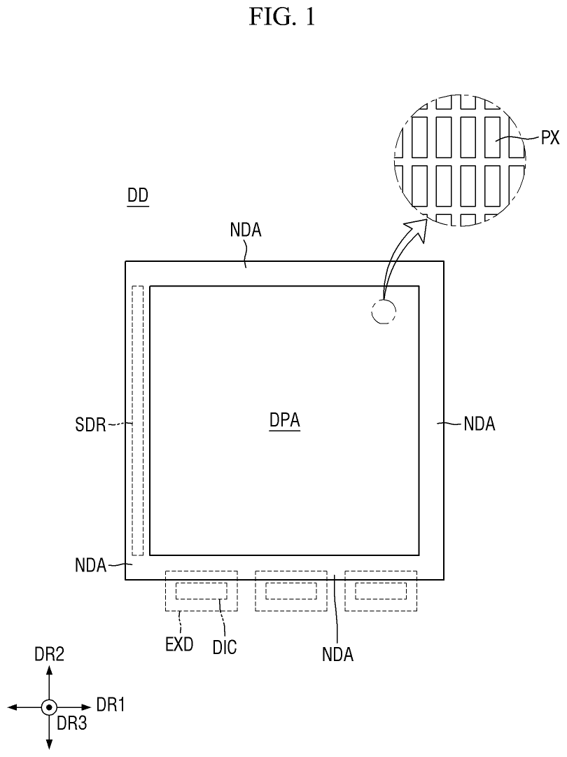

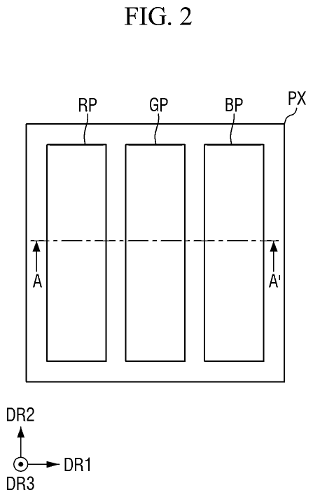

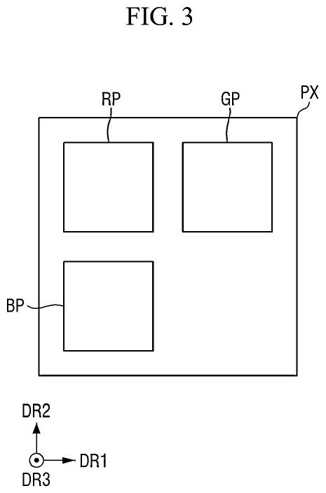

FIG. 1 is a schematic plan view of a display device according to an embodiment. FIG. 2 is a schematic diagram illustrating an example of a pixel of FIG. 1. FIG. 3 is a schematic diagram illustrating another example of a pixel of FIG. 1.

Referring to FIG. 1, a display device DD according to an embodiment may be applied to various consumer electronics, or internet of things devices, such as smartphones, cell phones, tablet PCs, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, and the like. A television is described herein as an example of the display device, and the television may have a high or ultra-high resolution, such as HD, UHD, 4K, 8K, etc.

In addition, the display device DD according to some embodiments may be categorized into various categories based on how it is displayed. For example, the classification of the display device may include an organic light emitting device (OLED), an inorganic light emitting device (inorganic EL), a quantum dot light emitting device (QED), a micro-LED display device (micro-LED), a nano-LED display device (nano-LED), a plasma display device (PDP), a field emission display device (FED), a cathode ray display device (CRT), a liquid crystal display device (LCD), an electrophoretic display device (EPD), and the like. A micro-LED display will be described below as an example of a display device, and the micro-LED display applied in the embodiments will be abbreviated simply as the display device unless otherwise noted. However, embodiments are not limited to micro-LED display devices, and other display devices listed above or known in the art may be applied.

Furthermore, in the following drawings, a first direction DR1 refers to a horizontal direction of the display device DD, a second direction DR2 refers to a vertical direction of the display device DD, and a third direction DR3 refers to a thickness direction of the display device DD. In this case, “left”, “right”, “up”, and “down” refer to directions when the display device 10 is viewed in plan view. For example, “right” refers to one side of the first direction DR1, “left” refers to the other side of the first direction DR1, “top” refers to one side of the second direction DR2, and “bottom” refers to the other side of the second direction DR2. Further, “upper” refers to a first side of the third direction DR3 and “lower” refers to a second side of the third direction DR3.

The display device DD according to an embodiment may have a circular, oval, or square shape in plan view, for example, a square shape. If the display device DD is a television, it may have a rectangular shape with the long sides located in the horizontal direction. However, embodiments are not limited to this configuration, and the long side may be positioned in the vertical direction and may be installed to be rotatable so that the long side may be variably positioned in the horizontal or vertical direction.

The display device DD may include a display area DPA and a non-display area NDA. The display area DPA may be an active area where the video is displayed. The display area DPA may have a square shape in plan view similar to the overall shape of the display device DD but may be circular or elliptical in shape, without limitation.

The display area DPA may include pixels PX. The pixels PX may be arranged (disposed) in a matrix orientation. The shape of each pixel PX may be rectangular or square in plan view, but is not limited thereto, and may also be rhombic in shape with each side inclined toward one side of the display device DD. The pixels PX may include multiple color pixels PX. For example, the pixels may include a first color pixel PX of red, a second color pixel PX of green, and a third color pixel PX of blue but are not limited thereto. Each color pixel PX may be alternately arranged in a stripe-type or a pentile-type.

The non-display area NDA may be disposed on the periphery of the display area DPA. The non-display area NDA may fully or partially enclose the display area DPA. The display area DPA may be any shape, such as circular or square. The non-display area NDA may be formed around the periphery of the display area DPA. The non-display area NDA may be composed of the bezel of the display device DD.

A driving circuit or a driving element for driving the display area DPA may be disposed in the non-display area NDA. In an embodiment, the non-display area NDA disposed adjacent to the first side (lower side in FIG. 1) of the display device DD may have a pad portion provided on the display substrate of the display device DD, and an external device EXD may be mounted on the pad electrode of the pad portion. Examples of the external device EXD include a connection film, a printed circuit board, a driving chip (DIC), a connector, a wiring connection film, and the like. In the non-display area NDA disposed adjacent to the second side (left side in FIG. 1) of the display device DD, a scan driving unit SDR, or the like formed directly on the display substrate of the display device DD may be disposed.

The display panel 100 may further include pixels PX as discussed above to display an image, scan lines extending in the first direction DR1, and data lines extending in the second direction DR2. The pixels PX may be arranged in a matrix form in the first direction DR1 and the second direction DR2.

Each of the pixels PX may include multiple sub-pixels RP, GP, and BP, as shown in FIGS. 2 and 3 and as discussed above. In FIGS. 2 and 3, each of the pixels PX includes three sub-pixels RP, GP, and BP, that is, a first sub-pixel RP, a second sub-pixel GP, and a third sub-pixel BP, but the embodiments of the specification are not limited thereto.

The first sub-pixel RP, the second sub-pixel GP, and the third sub-pixel BP may be connected to a data line and to at least one of the scan lines.

Each of the first sub-pixel RP, the second sub-pixel GP, and the third sub-pixel BP may have a rectangular, square, or rhombus planar shape. For example, each of the first sub-pixel RP, the second sub-pixel GP, and the third sub-pixel BP may have a rectangular planar shape having a short side in the first direction DR1 and a long side in the second direction DR2 as shown in FIG. 2. In other embodiments, each of the first sub-pixel RP, the second sub-pixel GP, and the third sub-pixel BP may have a planar shape of a square or rhombus including sides having the same length in the first direction DR1 and the second direction DR2 as shown in FIG. 3

As shown in FIG. 2, the first sub-pixel RP, the second sub-pixel GP, and the third sub-pixel BP may be arranged in the first direction DR1. In other embodiments, one of the second sub-pixel GP and the third sub-pixel BP and the first sub-pixel RP may be arranged in the first direction DR1, and the other one and the first sub-pixel RP may be arranged in the second direction DR2. For example, the first sub-pixel RP and the second sub-pixel GP may be arranged in the first direction DR1, and the first sub-pixel RP and the third sub-pixel BP may be arranged in the second direction DR2.

In other embodiments, one of the first sub-pixel RP and the third sub-pixel BP and the second sub-pixel GP may be arranged in the first direction DR1, and the other one and the third sub-pixel BP may be arranged in the second direction DR2. In other embodiments, one of the first sub-pixel RP and the second sub-pixel GP and the third sub-pixel BP may be arranged in the first direction DR1, and the other one and the third sub-pixel BP may be arranged in the second direction DR2.

The first sub-pixel RP may include a first light emitting element that emits first light, and the second sub-pixel GP may include a second light emitting element that emits second light, and the third sub-pixel BP may include a third light emitting element that emits third light. Here, the first light may be light in a red wavelength band, the second light may be light in a green wavelength band, and the third light may be light in a blue wavelength band. The red wavelength band may be a wavelength band of approximately 600 nm to approximately 750 nm, the green wavelength band may be a wavelength band of approximately 480 nm to approximately 560 nm, and the blue wavelength band may be a wavelength band of approximately 370 nm to approximately 460 nm, but the embodiments of the specification are not limited thereto.

Each of the first sub-pixel RP, the second sub-pixel GP, and the third sub-pixel BP may include an inorganic light emitting element having an inorganic semiconductor as a light emitting element emitting light. For example, the inorganic light emitting element may be a flip chip type micro light emitting diode (LED), but embodiments of the specification are not limited thereto.

As shown in FIGS. 2 and 3, the area of the first sub-pixel RP, the area of the second sub-pixel GP, and the area of the third sub-pixel BP may be substantially the same, but the disclosure is not limited thereto. At least one of the area of the first sub-pixel RP, the area of the second sub-pixel GP, and the area of the third sub-pixel BP may be different from the other one. In other embodiments, any two of the area of the first sub-pixel RP, the area of the second sub-pixel GP, and the area of the third sub-pixel BP may be substantially the same and the other one may be different from the above two. In other embodiments, the area of the first sub-pixel RP, the area of the second sub-pixel GP, and the area of the third sub-pixel BP may be different from each other.

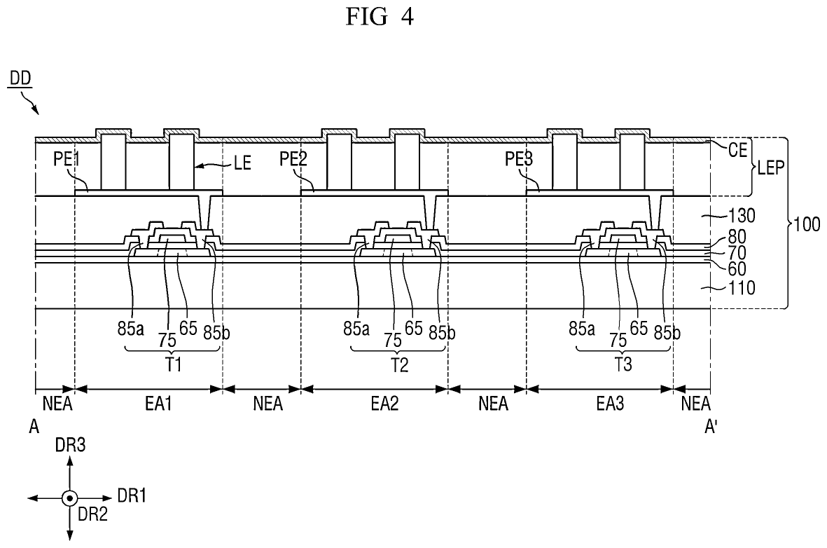

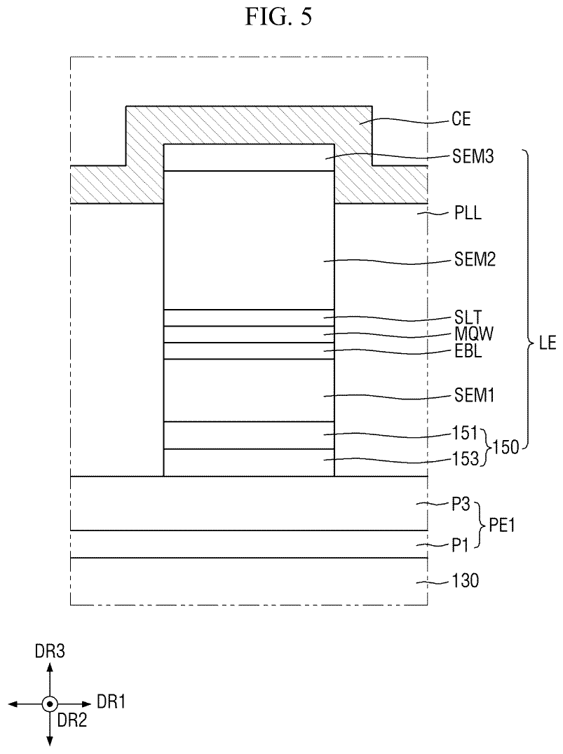

FIG. 4 is a schematic cross-sectional view illustrating a display device according to an embodiment. FIG. 5 is a schematic cross-sectional view illustrating a pixel electrode and a light emitting element according to an embodiment.

Referring to FIGS. 4 and 5, the display panel 100 may include a first substrate 110 and a light emitting element portion LEP disposed on the first substrate 110. The first substrate 110 may be an insulating substrate. The first substrate 110 may include a transparent material. For example, the first substrate 110 may include a transparent insulating material such as glass, quartz, or the like. The first substrate 110 may be a rigid substrate. However, the first substrate 110 is not limited thereto and may include a plastic, such as polyimide, or the like. The first substrate 110 may have flexible characteristics that allow it to be warped, bent, folded, or rolled. Emitting areas EA1, EA2, and EA3 and non-emitting areas NEA may be defined on the first substrate 110.

Switching elements T1, T2, and T3 may be disposed on the first substrate 110. In an embodiment, the first switching element T1 may be disposed in the first light emitting area EA1 of the first substrate 110, the second switching element T2 may be disposed in the second light emitting area EA2, and the third switching element T3 may be disposed in the third light emitting area EA3. However, embodiments are not limited to this configuration, and at least one of the first switching element T1, the second switching element T2, and the third switching element T3 may be disposed in the non-emitting area NEA in other embodiments.

In an embodiment, the first switching element T1, the second switching element T2, and the third switching element T3 may each be a thin film transistor including an amorphous silicon, polysilicon, or oxide semiconductor. Although not shown, there may be signal lines (e.g., gate lines, data lines, power supply lines, etc.) further disposed on the first substrate 110 that carry signals to each switching element.

Each switching element T1, T2, and T3 may include a semiconductor layer 65, a gate electrode 75, a source electrode 85a, and a drain electrode 85b. Specifically, a buffer layer 60 may be disposed on the first substrate 110. The buffer layer 60 may be disposed to cover a front side of the substrate 110. The buffer layer 60 may include a silicon nitride, a silicon oxide, or a silicon oxynitride, and may be a single layer or a double layer thereof.

The semiconductor layer 65 may be disposed on the buffer layer 60. The semiconductor layer 65 may form a channel of each of the switching elements T1, T2, and T3. The semiconductor layer 65 may include amorphous silicon, polycrystalline silicon, or an oxide semiconductor. In an example, the oxide semiconductor, for example, may include a binary compound (ABx), a ternary compound (ABxCy), or a tetracyclic compound (ABxCyDz) containing indium, zinc, gallium, tin, titanium, aluminum, hafnium (Hf), zirconium (Zr), magnesium (Mg), and the like. In an embodiment, the semiconductor layer 65 may include indium tin zinc oxide (IGZO).

A gate insulating layer 70 may be disposed on the semiconductor layer 65. The gate insulating layer 70 may include a silicon compound, a metal oxide, or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, and the like. In an embodiment, the gate insulating layer 70 may include a silicon oxide.

The gate electrode 75 may be disposed on the gate insulating layer 70. The gate electrode 75 may overlap the semiconductor layer 65. The gate electrode 75 may include a conductive material. The gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium but is not limited thereto.

An interlayer insulating layer 80 may be disposed on the gate electrode 75. The interlayer insulating layer 80 may include an inorganic insulating material such as a silicon oxide, a silicon nitride, a silicon oxynitride, a hafnium oxide, an aluminum oxide, a titanium oxide, a tantalum oxide, a zinc oxide, and the like.

The source electrode 85a and a drain electrode 85b may be disposed on the interlayer insulating layer 80. The source electrode 85a and the drain electrode 85b may be connected to the semiconductor layer 65 through contact holes penetrating the interlayer insulating layer 80 and the gate insulating layer 70, respectively. The source electrode 85a and the drain electrode 85b may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed of a Cu/Ti double layer in which an upper layer of copper is stacked on a lower layer of titanium but is not limited thereto.

A first planarization layer 130 may be disposed on the first switching element T1, the second switching element T2, and the third switching element T3. In an embodiment, the first planarization layer 130 may be a planarization layer and may include an organic material. For example, the first planarization layer 120 may include an acrylic resin, an epoxy resin, an imide resin, an ester resin, or the like. In an embodiment, the first planarization layer 120 may include a positive photosensitive material or a negative photosensitive material.

The light emitting element portion LEP may be disposed on the first planarization layer 130. The light emitting element portion LEP may include pixel electrodes PE1, PE2, and PE3, light emitting elements LE, and a common electrode CE.

The pixel electrodes PE1, PE2, and PE3 may include a first pixel electrode PE1, a second pixel electrode PE2, and a third pixel electrode PE3. The first pixel electrode PE1, the second pixel electrode PE2, and the third pixel electrode PE3 may serve as the first electrode of the light emitting element LE and may be the anode electrode or the cathode electrode. The first pixel electrode PE1 may be disposed in the light emitting area EA1, the second pixel electrode PE2 may be disposed in the second light emitting area EA2, and the third pixel electrode PE3 may be disposed in the third light emitting area EA3. In an embodiment, the first pixel electrode PE1 may fully overlap the first light emitting area EA1, the second pixel electrode PE2 may fully overlap the second light emitting area EA2, and the third pixel electrode PE3 may fully overlap the third light emitting area EA3. The first pixel electrode PE1 may penetrate the first planarization layer 130 and be connected to the first switching element T1, the second pixel electrode PE2 may penetrate the first planarization layer 130 and be connected to the second switching element T2, and the third pixel electrode PE3 may penetrate the first planarization layer 130 and be connected to the third switching element T3.

The first pixel electrode PE1, the second pixel electrode PE2, and the third pixel electrode PE3 may include metal. The metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. The first pixel electrode PE1, the second pixel electrode PE2, and the third pixel electrode PE3 may have a multilayer structure in which two or more metal layers are stacked on each other. For example, the first pixel electrode PE1, the second pixel electrode PE2, and the third pixel electrode PE3 may have a two-layer structure in which a copper layer is stacked on a titanium layer but is not limited thereto.

Referring to FIG. 5, in this embodiment, each pixel electrode PE1, PE2, and PE3 may include a lower electrode layer P1 and an upper electrode layer P3. In the following, the first pixel electrode PE1 will be described as an example.

The lower electrode layer P1 may be disposed at the bottom of the first pixel electrode PE1 and may be electrically connected to the switching element. The lower electrode layer P1 may serve to provide the first pixel electrode PE1 with adhesion to the first planarization layer 130. The lower electrode layer P1 may include a metal, for example, titanium.

The upper electrode layer P3 may be disposed on the lower electrode layer P1 and may be in direct contact with the light emitting element LE. The upper electrode layer P3 may be disposed between the lower electrode layer P1 and the light emitting element LE and may serve to provide the first pixel electrode PE1 with adhesion to the light emitting element LE. The upper electrode layer P3 may include a metal, for example, copper.

The light emitting elements LE may be disposed on each of the first pixel electrode PE1, the second pixel electrode PE2, and the third pixel electrode PE3.

As shown in FIGS. 4 and 5, the light emitting elements LE may be disposed in the first light emitting area EA1, the second light emitting area EA2, and the third light emitting area EA3, respectively. The light emitting element LE may be a vertical light emitting diode element extending long in the third direction DR3. That is, the length of the light emitting element LE in the third direction DR3 may be longer than that in the horizontal direction. The length in the horizontal direction refers to the length of the first direction DR1 or the length of the second direction DR2. For example, the length of the light emitting element LE in the third direction DR3 may be approximately 1 to approximately 5 μm.

The light emitting element LE may be a micro light emitting diode element. The light emitting element LE may include a connection electrode 150, a first semiconductor layer SEM1, an electron blocking layer EBL, an active layer MQW, a superlattice layer SLT, a second semiconductor layer SEM2, and a third semiconductor layer SEM3 in the thickness direction of the display panel 100, that is, the third direction DR3. The connection electrode 150, the first semiconductor layer SEM1, the electron blocking layer EBL, the active layer MQW, the superlattice layer SLT, the second semiconductor layer SEM2, and the third semiconductor layer SEM3 may be stacked sequentially in the third direction DR3.

The light emitting element LE may have a cylindrical, disk, or rod shape with a width longer than a height. However, embodiments are not limited to this configuration, and the light emitting element LE may have the shape of a rod, wire, tube, or the like, a polygonal shape such as a cube, a rectangle, a hexagon, or a shape that extends in a direction but has a partially inclined outer surface.

The connection electrode 150 may be disposed on top of each of the pixel electrodes PE1, PE2, and PE3. In the following, the light emitting element LE disposed on the first pixel electrode PE1 will be described as an example, but is not limited thereto, and the structure of the light emitting element LE disposed on the second pixel electrode PE2 and the third pixel electrode PE3 may be configured the same.

The connection electrode 150 may include a reflective layer 151 and a connection layer 153. The reflective layer 151 may serve to reflect light emitted from the active layer MQW of the light emitting element LE. The reflective layer 151 may be disposed adjacent to the active layer MQW of the light emitting element LE. The reflective layer 151 may include a metal material that is conductive and has a high light reflectance. The reflective layer 151 may include, for example, aluminum (Al) or silver (Ag), or may be an alloy thereof.

The connection layer 153 may serve to transmit an emission signal from the first pixel electrode PE1 to the light emitting element LE. The connection layer 153 may be an ohmic connection electrode. However, the electrode is not limited to this configuration and may be a Schottky connection electrode. The connection layer 153 may be disposed at the bottom of the light emitting element LE and may be disposed farther from the active layer MQW than the reflective layer 151. The connection layer 153 may include at least one of gold (Au), copper (Cu), tin (Sn), silver (Ag), aluminum (Al), and titanium (Ti). For example, the connection layer 153 may include a 9:1 alloy, 8:2 alloy, or 7:3 alloy of gold and tin, or may include an alloy of copper, silver, and tin (SAC305).

FIG. 5 illustrates that the light emitting element LE includes the connection electrode 150 that is a double-layer structure of the reflective layer 151 and the connection layer 153 but is not limited thereto. In some cases, the light emitting element LE may include the connection electrode 150 in which a greater number of layers are stacked on the connection electrode 150, or some layers may be omitted.

The first semiconductor layer SEM1 may be disposed on the connection electrode 150. The first semiconductor layer SEM1 may be a p-type semiconductor and may include a semiconductor material having a chemical formula of AlxGayIn1-x-yN (0≤x≤1, 0≤y≤1, 0≤x+y≤1). For example, the first semiconductor layer SEM1 may be any one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. The thickness of the first semiconductor layer SEM1 may range from approximately 30 nm to approximately 200 nm but is not limited thereto.

The electron blocking layer EBL may be disposed on the first semiconductor layer SEM1. The electron blocking layer EBL may be a layer to suppress or prevent too many electrons from flowing into the active layer MQW. For example, the electron blocking layer EBL may be p-AlGaN doped with p-type Mg. The thickness of the electron blocking layer EBL may range from approximately 10 nm to approximately 50 nm but is not limited thereto. Additionally, the electron blocking layer EBL may be omitted.

The active layer MQW may be disposed on the electron blocking layer EBL. The active layer MQW may emit light by combining electron-hole pairs according to an electrical signal applied through the first semiconductor layer SEM1 and the second semiconductor layer SEM2. The active layer MQW may emit first light having a central wavelength band ranging from approximately 450 nm to approximately 495 nm, that is, light in a blue wavelength band.

The active layer MQW may include a single or multiple quantum well structure. If the active layer includes a material with a multi-quantum well structure, it may be a stacked structure with well layers and a barrier layer alternating with each other. The well layer may be formed of InGaN and the barrier layer may be formed of GaN or AlGaN, but is not limited thereto.

In other embodiments, the active layer MQW may have a structure in which a semiconductor material having a large band gap energy and a semiconductor material having a small band gap energy are alternately stacked with each other and may include other Group 3 to Group 5 semiconductor materials depending on the wavelength band of the emitted light. The light emitted by the active layer MQW is not limited to the first light, and in some cases, it may emit second light (light in the green wavelength band) or third light (light in the red wavelength band). In an embodiment, in case that indium is included among the semiconductor materials included in the active layer MQW, the color of the emitted light may vary depending on the indium content. For example, if the indium content decreases, the wavelength band of the emitted light may shift to the red wavelength band, and if the indium content increases, the wavelength band of the emitted light may shift to the blue wavelength band.

The superlattice layer SLT may be disposed on the active layer MQW. The superlattice layer SLT may be a layer for relieving stress between the second semiconductor layer SEM2 and the active layer MQW. For example, the superlattice layer SLT may be formed of InGaN or GaN. The thickness of the superlattice layer SLT may be approximately 50 to approximately 200 nm. The superlattice layer SLT may be omitted.

The second semiconductor layer SEM2 may be disposed on the superlattice layer SLT. The second semiconductor layer SEM2 may be the n-type semiconductor. The second semiconductor layer SEM2 may include a semiconductor material having the formula AlxGayIn1-x-yN (0≤x≤1, 0≤y≤1, 0≤x+y≤1). For example, it may be one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may range from approximately 2 μm to approximately 4 μm but is not limited thereto.

The third semiconductor layer SEM3 may be disposed on the second semiconductor layer SEM2. The third semiconductor layer SEM3 may be disposed between the second semiconductor layer SEM2 and the common electrode CE. The third semiconductor layer SEM3 may be an undoped semiconductor. The third semiconductor layer SEM3 may include the same material as the second semiconductor SEM2 but may be a material that is not doped with an n-type or p-type dopant. In an embodiment, the third semiconductor layer SEM3 may be at least one of undoped InAlGaN, GaN, AlGaN, InGaN, AlN, and InN but is not limited thereto.

A second planarization layer PLL may be disposed on the pixel electrodes PE1, PE2, and PE3 and the first planarization layer 130. The second planarization layer PLL may flatten the lower step so that the common electrode CE, which will be described later, may be formed. The second planarization layer PLL may be formed at a predetermined height so that at least a portion of the light emitting elements LE, for example, the upper portion, protrudes above the top of the second planarization layer PLL. In other words, the height of the second planarization layer PLL relative to the top surface of the first pixel electrode PE1 may be less than the height of the light emitting element LE.

The second planarization layer PLL may include an organic material to flatten the lower step. For example, the second planarization layer PLL may include a polyacrylates resin, epoxy resin, phenolic resin, polyamides resin, polyimides resin, unsaturated polyesters resin, poly phenylenethers resin, polyphenylenesulfides resin, or benzocyclobutene (BCB).

The common electrode CE may be disposed on the second planarization layer PLL and the light emitting elements LE. Specifically, the common electrode CE may be disposed on a surface of the first substrate 110 on which the light emitting element LE is formed and may be disposed throughout the display area DPA and the non-display area NDA. The common electrode CE may overlap each of the light emitting areas EA1, EA2, and EA3 in the display area DPA, and may be made of a thin thickness so that light may be emitted.

The common electrode CE may be directly disposed on the top and side surfaces of the light emitting elements LE. The common electrode CE may directly contact the second semiconductor layer SEM2 and the third semiconductor layer SEM3 on the side surfaces of the light emitting element LE. As shown in FIG. 4, the common electrode CE covers the light emitting elements LE and may be a common layer arranged to commonly connect the light emitting elements LE. Since the conductive second semiconductor layer SEM2 has a structure in which each light emitting element LE is patterned, the common electrode CE may directly contact a side of the second semiconductor layer SEM2 of each light emitting element LE so that a common voltage may be applied to each light emitting element LE.

Since the common electrode CE is disposed entirely on the first substrate 110 and applies a common voltage, it may include a material with low resistance. Additionally, the common electrode CE may be formed to be thin to facilitate light transmission. For example, the common electrode CE may include a material with low resistance, such as aluminum (Al), silver (Ag), copper (Cu), or the like. The thickness of the common electrode CE may be approximately 10Å to approximately 200Å but is not limited thereto.

The above-described light emitting elements LE may receive a pixel voltage or anode voltage from each pixel electrode PE1, PE2, and PE3, and may receive a common voltage through the common electrode CE. The light emitting elements LE may emit light with a predetermined luminance depending on the voltage difference between the pixel voltage and the common voltage.

In an embodiment, by disposing multiple light emitting elements LE, that is, inorganic light emitting diodes, on the pixel electrodes PE1, PE2, and PE3, it is possible to eliminate the disadvantages of organic light emitting diodes that are vulnerable to external moisture or oxygen, and to improve the life and reliability.

A wavelength conversion portion may be disposed on the light emitting element portion LEP. The wavelength conversion portion may include a partition wall, a wavelength conversion layer, color filters, a light blocking member, and a protective layer.

The partition wall is disposed on the common electrode CE of the display area DPA and may compartmentalize multiple light emitting areas EA1, EA2, and EA2. The partition wall is arranged to extend in the first direction DR1 and the second direction DR2 and may be formed in a grid-like pattern throughout the display area DPA. Furthermore, the partition wall may not overlap with the light emitting areas EA1, EA2, and EA3 and may overlap with the non-lemitting area NEA.

The partition wall may include openings exposing the lower common electrode CE. The openings may include a first opening overlapping the first light emitting area EA1, a second opening overlapping the second light emitting area EA2, and a third opening overlapping a third light emitting area EA3. Here, the openings may correspond to the light emitting areas EA1, EA2, and EA3. That is, the first opening corresponds to the first light emitting area EA1, the second opening corresponds to the second light emitting area EA2, and the third opening corresponds to the third light emitting area EA3.

The partition wall may serve to provide space for the wavelength conversion layer to be formed. For this purpose, the partition wall may be made of a predetermined thickness. For example, the thickness of the partition wall may be in the range of 1 μm to 10 μm. The partition wall may include an organic insulating material so as to have a predetermined thickness. The organic insulating material may include, for example, epoxy-based resin, acrylic-based resin, cardo-based resin, or imide-based resin.

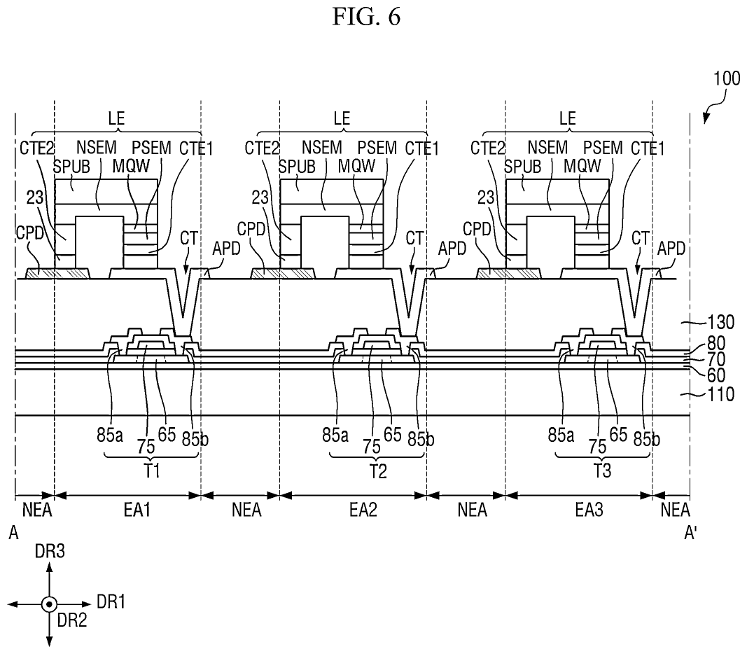

Referring to FIGS. 4 and 5, a vertical light emitting element is adopted, but an embodiment of the disclosure is not limited thereto, and a flip-chip type light emitting element may be adopted as shown in FIG. 6, which will be described later.

FIG. 6 is a schematic cross-sectional view illustrating a display device according to another embodiment.

Referring to FIG. 6, the display panel 100 may be different from the display panel 100 of FIG. 4 at least in that it adopts a flip-chip type light emitting element.

The light emitting element LE is a flip-chip type micro LED in which the first contact electrode CTE1 and the second contact electrode CTE2 are disposed to face the anode pad electrode APD and the cathode pad electrode CPD. The light emitting element LE may be an inorganic light emitting element made of an inorganic material such as GaN. The light emitting element LE may have a length in the first direction DR1, a length in the second direction DR2, and a length in the third direction DR3 of several to several hundred μm each. For example, the length of the light emitting element LE in the first direction DR1, the length in the second direction DR2, and the length in the third direction DR3 may each be approximately 100 μm or less.

The light emitting elements LE may be formed by growth on a semiconductor substrate such as a silicon wafer. Each of the light emitting elements LE may be directly transferred from the silicon wafer onto the anode pad electrode APD and cathode pad electrode CPD of the substrate SUB. The first contact electrode CTE1 and the anode pad electrode APD may be bonded to each other through a bonding process. Additionally, the second contact electrode CTE2 and the cathode pad electrode CPD may be bonded to each other through the bonding process. The first contact electrode CTE1 and the anode pad electrode APD may be electrically connected to each other through a bonding electrode 23. Further, the second contact electrode CTE2 and the cathode pad electrode CPD may be electrically connected to each other through the bonding electrode 23.

For example, the bonding electrode 23 may be disposed on a surface of the light emitting element LE. The bonding electrode 23 may be a bonded product of pressing melt bonding using a laser. Here, pressing melt bonding refers to a state in which the bonding electrode 23 is melted under heat so that the light emitting element LE, the enode pad electrode APD, and the cathode pad electrode CPD are melt-mixed and cooled to a solid state in case that the laser supply is terminated. While cooled and solidified in the melted mixed state, the conductivity of the light emitting element LE and the enode pad electrode APD and cathode pad electrode CPD is maintained, so that the enode pad electrode APD and cathode pad electrode CPD and the light emitting element LE may be electrically connected and physically connected respectively. Accordingly, the bonding electrode 23 may be disposed on the first contact electrode CTE1 and the second contact electrode CTE2 of the light emitting element LE.

The bonding electrode 23 may include, for example, Au, AuSn, PdIn, InSn, NiSn, Au-Au, AgIn, AgSn, Al, Ag, or carbon nanotubes CNT. Each of these may be utilized alone or in combination with two or more.

Each of the light emitting elements LE may be a light emitting structure including a base substrate SPUB, an n-type semiconductor NSEM, an active layer MQW, a p-type semiconductor PSEM, a first contact electrode CTE1, and a second contact electrode CTE2.

The base substrate SPUB may be a sapphire substrate, but embodiments of the specification are not limited thereto.

The n-type semiconductor NSEM may be disposed on a side of the base substrate SPUB. For example, the n-type semiconductor NSEM may be disposed on the bottom surface of the base substrate SPUB. The n-type semiconductor NSEM may be made of GaN doped with n-type conductive dopants such as Si, Ge, Sn, and the like.

The active layer MQW may be disposed on a portion of a side of the n-type semiconductor NSEM. Since the active layer MQW has been described with reference to FIGS. 4 and 5, overlapping descriptions will be omitted.

The p-type semiconductor PSEM may be disposed on a side of the active layer MQW. The p-type semiconductor PSEM may be made of GaN doped with p-type conductive dopants such as Mg, Zn, Ca, Se, Ba, and the like. The p-type semiconductor PSEM may correspond to the first semiconductor layer SEM1 of the light emitting element LE described with reference to FIGS. 4 and 5.

The first contact electrode CTE1 may be disposed on a side of the p-type semiconductor PSEM, and the second contact electrode CTE2 may be disposed on another side of the n-type semiconductor NSEM. The first contact electrode CTE1 and the second contact electrode CTE2 may not directly contact each other. Another part of a surface of the n-type semiconductor NSEM on which the second contact electrode CTE2 is disposed may be disposed away from a part of a surface of the n-type semiconductor NSEM on which the active layer MQW is disposed.

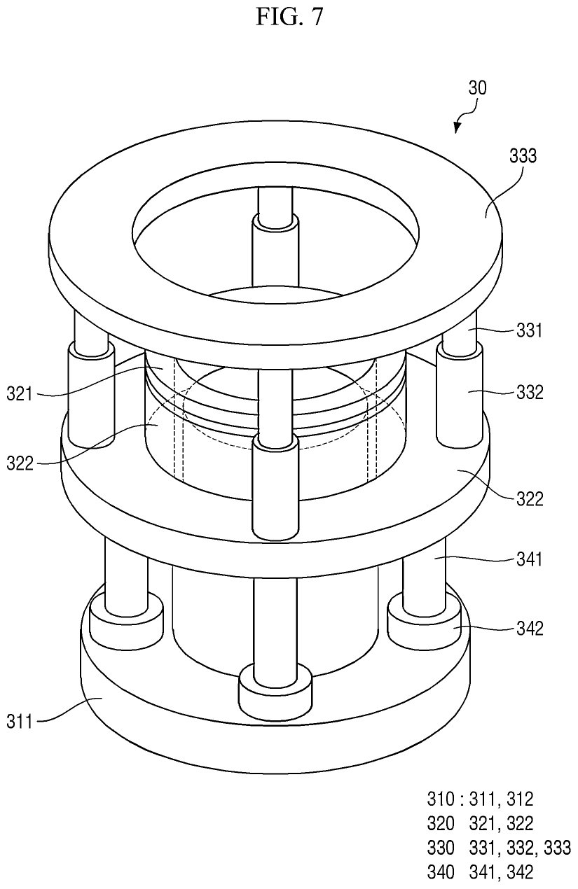

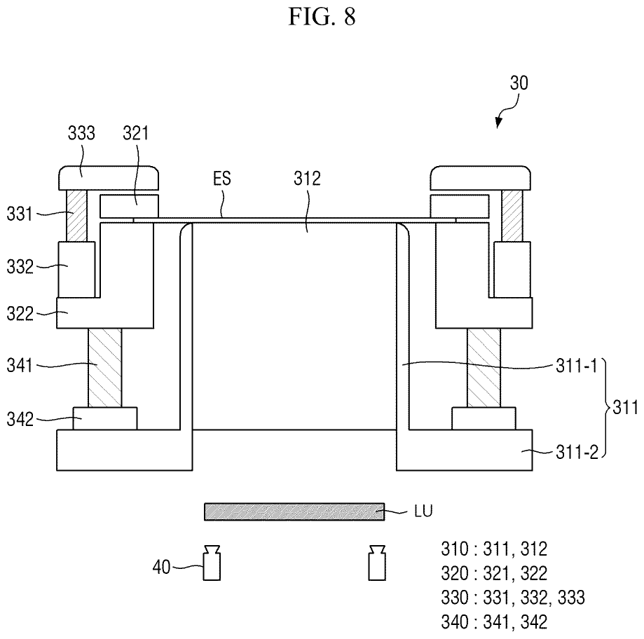

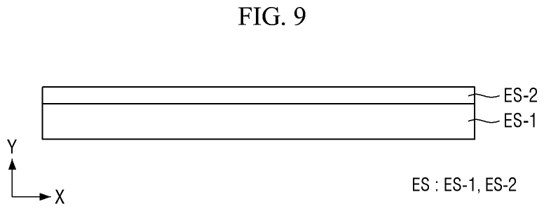

FIG. 7 is a schematic perspective view of a transfer film stretching device according to an embodiment of the disclosure. FIG. 8 is a schematic diagram illustrating the structure of a transfer film stretching device according to an embodiment of the disclosure. FIG. 9 is a schematic side view illustrating the structure of a transfer film according to an embodiment of the disclosure.

Referring to FIGS. 7 and 8, a transfer film stretching device 30 is a device that stretches the entire width of a transfer film ES for transferring the light emitting element LE in the outer peripheral direction.

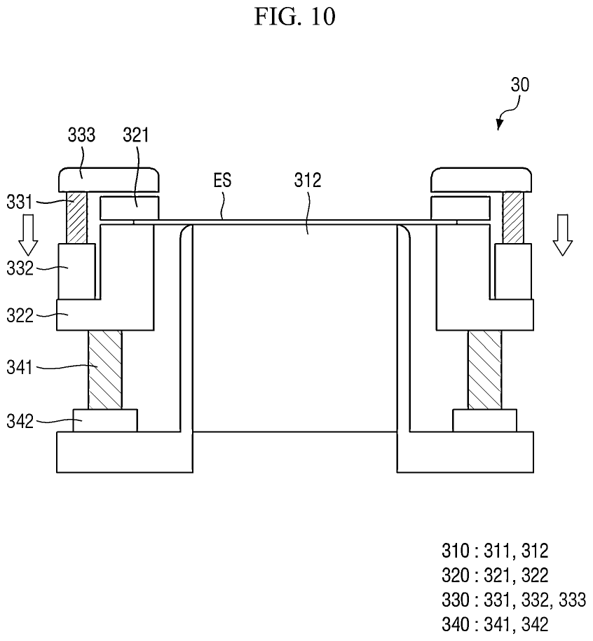

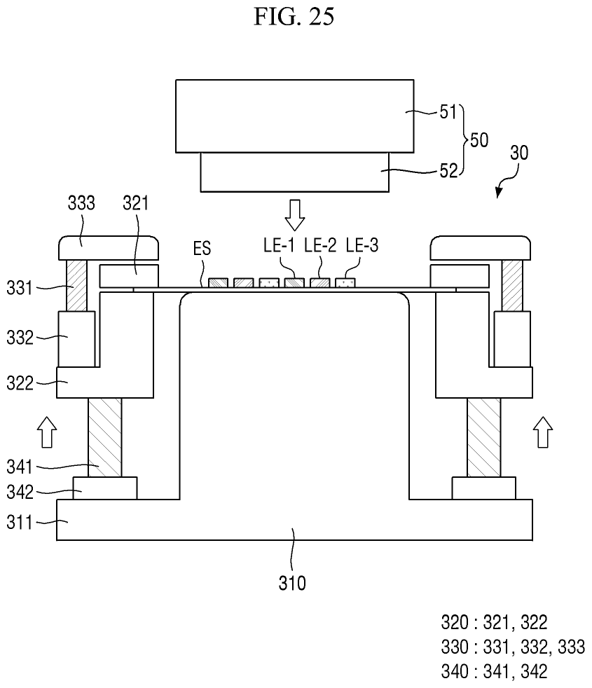

The degree of stretching may be set and applied differently depending on at least one of the requirements of the size and diameter of the transfer film ES, the array width or arrangement spacing of the light emitting elements LE to be transferred later, and the stretching width of the transfer film ES. The stretching of the transfer film ES will be described with reference to FIGS. 10 to 25.

First, referring to FIG. 9, the transfer film ES may be formed of a stretchable, elastic polymer material. The transfer film ES may be a material with the same amount of elongation in all directions. Therefore, the amount of change in position of the outermost light emitting element and the amount of change in position of other parts may be the same. The stretchable elastic polymer materials may include, for example, polyolefine, polyvinyl chloride (PVC), elastomeric silicone, elastomeric polyurethane, elastomeric polyisoprene, and the like. The transfer film ES may be composed of a support layer ES-1 and an adhesive layer ES-2 disposed on the support layer ES-1. The support layer ES-1 may be made of a material that is transparent and mechanically stable to allow light to transmit through it. For example, the support layer ES-1 may include a transparent polymer such as polyester, polyacrylic, polyepoxy, polyethylene, polystyrene, polyethylene terephthalate, or the like. The adhesive layer ES-2 may include an adhesive material for adhering the light emitting element (LE). For example, the adhesive material may include urethane acrylate, epoxy acrylate, polyester acrylate, and the like. The adhesive material may be a material whose adhesive strength changes as ultraviolet rays (UV) or heat is applied, and thus the adhesive layer may be easily separated from the light emitting element LE.

Referring again to FIGS. 7 and 8, the transfer film stretching device 30 includes a support portion 310 and stretching portions 320, 330, and 340. The transfer film stretching device 30 may further include a vision member 40 and a laser irradiation member LU. The vision member 40 and the laser irradiation member LU may be disposed at a lower portion of the support frame 311.

At least one vision member 40 may be disposed at a lower portion of a laser transmitting portion 312 and facing in a frontward direction. The vision member 40 may photograph light emitting elements LE or the like arranged on the transfer film ES through the laser transmitting portion 312. The arrangement state of the light emitting elements LE and the substrate 110 may be monitored through the image captured by at least one vision member 40. The vision member 40 may be a camera but is not limited thereto. For example, it may be an optical device including a light emitting member and a light receiving member.

The vision member 40 makes it possible to check the separation distance or arrangement of the light emitting elements LE disposed on the transfer film ES.

The laser irradiation member LU may be disposed at a lower portion of the laser transmitting portion 312 and may irradiate the laser in the front direction. The light emitted from the laser irradiation member LU may pass through the laser transmitting portion 312 and apply the laser to the transfer film ES of the support portion 310.

The support portion 310 may include the support frame 311 and the laser transmitting portion 312.

The support frame 311 may support the transfer film ES while stretching the entire width of the transfer film ES in the the outer peripheral direction.

An opening may be formed in the center of the support frame 311, and the laser transmitting portion 312 may be disposed in the opening.

The support frame 311 may include a central portion 311-1 and a side portion 311-2.

The center portion 311-1 and the side portion 311-2 may have a cylindrical shape. The diameter of the side portion 311-2 may be larger than the diameter of the central portion 311-1. The height of the side portion 311-2 may be lower than the height of the center portion 311-1. The side portion 311-2 may surround the central portion 311-2 at a bottom portion of the central portion 311-1.

The laser transmitting portion 312 may be formed and arranged in a cylindrical shape corresponding to the shape and size of the opening of the cylindrical support frame 311.

The laser transmitting portion 312 may transmit a laser and may heat the light emitting element LE during the bonding process of the light emitting element LE.

The laser transmitting portion 312 may be implemented, for example, with quartz, sapphire, fused silica glass, or diamond. However, the physical properties of the laser transmitting portion 312 implemented with quartz material may be different from those of the laser transmitting portion 312 implemented with sapphire. For example, in case of irradiating an approximate 980 nm laser, the transmittance of the laser transmitting portion 312 implemented in the quartz material may be approximately 85% to approximately 99%, while the transmittance of the laser transmitting portion 312 implemented in the sapphire may be approximately 80% to approximately 90%.

The stretching portions 320, 330, and 340 may have a cylindrical shape with an opening. The central portion 311-1 of the support frame 311 may be disposed in the opening. The stretching portions 320, 330, and 340 may be arranged to surround the central portion 311-1 of the support frame 311. The inner surfaces of the stretching portions 320, 330, and 340 may be arranged to be spaced apart from the outer surfaces of the central portion 311-1 of the support frame 311. Therefore, in case that the stretching portions 320, 330, and 340 move up and down, friction between the stretching portions 320, 330, and 340 and the support portion 310 may not occur. The stretching portions 320, 330, and 340 may be disposed on the side portion 311-2 of the support frame 311. In other words, the side portion 311-2 of the support frame 311 may support the stretching portions 320, 330, and 340.

The stretching portions 320, 330, and 340 may include a film fixing portion 320, a first upper and lower driving portion 330, and a second upper and lower driving portion 340.

The film fixing portion 320 may include a fixing frame 321 and a fixing bottom portion 322. The fixing frame 321 and the fixing bottom portion 322 may form a pair. The fixing frame 321 may overlap the upper part of the fixing bottom portion 322. Therefore, the fixing frame 321 may also be referred to as a fixed top portion. The fixing frame 321 may be formed in the form of a circular ring or a ring-type frame. The fixing bottom portion 322 may support the fixing frame 321 and the first upper and lower driving portion 330, which will be described later. The fixing bottom portion 322 may have a support ‘L’ shape. The fixing frame 321 may be disposed at the top of the ‘L’ shaped shape.

The top surface of the fixing bottom portion 322 may be disposed on the same plane as the top surface of the support frame 311 in a ready state. The ready state may be a state before the transfer film ES is mounted and the stretching portions 320, 330, and 340 are raised or lowered to perform stretching.

The first upper and lower driving portion 330 may be disposed adjacent to the film fixing portion 320 and may press the film fixing portion 320 in the other direction (downward) of the third direction. Accordingly, the first upper and lower driving portion 330 may fix the film fixing portion 320. The first upper and lower driving portion 330 may be disposed further away from the support frame 311 than the film fixing portion 320.

The first upper and lower driving portion 330 may be formed as a hydraulic pumping type such as a piston but is not limited thereto. For example, a side of the first upper and lower driving portion 330 may be assembled on the back of a pressing frame 333, and another side may be assembled with a pneumatic or hydraulic pressure regulator. Accordingly, the first upper and lower driving portion 330 may move the pressing frame 333 in one direction or the other direction of the third direction by using the pneumatic or hydraulic pressure regulator.

The first upper and lower driving portion 330 may include a first inner driving portion 331, a first outer driving portion 332, and a pressing frame 333.

The first inner driving portion 331 and the first outer driving portion 332 may be disposed around the film fixing portion 320 in a columnar shape.

The first inner driving portion 331 may be disposed on the first outer driving portion 332, and the first inner driving portion 331 may be connected to a first upward driving motor (not shown) and may be movable in a first direction (upward) and a second direction (downward) in the third direction.

In case that the first inner driving portion 331 moves in the other direction of the third direction, the first inner driving portion 331 may be inserted into the first outer driving portion 332. In an embodiment, the first inner driving portion 331 and the first outer driving portion 332 are used as examples to drive the first upper and lower driving portion 330 in one direction or the other of the third direction, but the disclosure is not limited thereto.

The pressing frame 333 may overlap the film fixing portion 320 at the top in the third direction of the film fixing portion 320. The pressing frame 333 may be disposed on the top of the first upper and lower driving portion 330. For example, the pressing frame 333 may be disposed on the top of the first inner driving portion 331, and the first inner driving portion 331 may support the pressing frame 333. In case that the first inner driving portion 331 moves in the other direction of the third direction, the pressing frame 333 may move in the other direction of the third direction together with the first inner driving portion 331.

The pressing frame 333 may protrude toward the fixing frame 321 rather than the first inner driving portion 331 and may overlap the film fixing portion 320.

The pressing frame 333 may be formed in the form of a polygonal panel or frame such as a circle or square with a circular opening. Such the pressing frame 333 may be fixed by circularly pressing the outer periphery of the transfer film ES, excluding the opening area, by the circular opening and the frame around the opening. The opening structure may be formed in a polygonal shape such as an oval or a square depending on the stretching direction of the transfer film ES, but it is preferable to apply a circular opening to press and fix the outer periphery of the transfer film ES in a circular manner to even out the stretching direction of the transfer film ES. By stretching the transfer film ES after circularly pressing and fixing the outer periphery of the transfer film ES, the entire surface of the transfer film ES is stretched with the same strength. Therefore, if the spacing distances between the light emitting elements LE arranged on the transfer film ES before stretching are the same, the spacing distance between the light emitting elements LE arranged on the transfer film ES even after stretching may also be the same. Since the stretching strength at various positions on the transfer film ES is the same, the spacing distance between the light emitting elements LE at various positions on the transfer film ES may be the same.

The fixing frame 321 may be disposed between the pressing frame 333 and the fixing bottom portion 322. In case that the pressing frame 333 moves in the other direction of the third direction, the pressing frame 333 may press the fixing frame 321.

The outer periphery of the transfer film ES may be located between the fixing frame 321 and the fixing bottom portion 322. Therefore, in case that the pressing frame 333 presses the fixing frame 321, the fixing frame 321 and the fixing bottom portion 322 may fix the outer periphery of the transfer film ES.

The second upper and lower driving portion 340 may be arranged to be spaced apart around the center portion 311-1 of the support frame 311. The second upper and lower driving portion 340 may be disposed at a lower portion of the first upper and lower driving portion 330 and the film fixing portion 320.

The second upper and lower driving portion 340 may be formed of a hydraulic pumping type such as a piston, and a side may be assembled on the back of the first upper and lower driving portion 330 and the other side may be assembled with the pneumatic or hydraulic pressure regulator. Accordingly, the second upper and lower driving portion 340 may move the first upper and lower driving portion 330 and the film fixing unit 320 in one or the other direction of the third direction by using the pneumatic or hydraulic pressure regulator.

In an embodiment, the second upper and lower driving portion 340 may include a second inner driving portion 341 and a second outer driving portion 342.

The second inner driving portion 341 and the second outer driving portion 342 may be arranged to be spaced apart from each other around the support frame 311.

The second inner driving portion 341 may be disposed on the second outer driving portion 342, and the second inner driving portion 341 may be connected to a second upward driving motor (not shown) and may move in one direction (upward) and the other direction (downward) in the third direction.

In case that the second inner driving portion 341 moves in the other direction of the third direction, the second inner driving portion 341 may be inserted into the second outer driving portion 342.

The first upper and lower driving portion 330 and the film fixing portion 320 may be disposed on the second inner driving portion 341. Therefore, in case that the second inner driving portion 341 moves in the other direction of the third direction, the first upper and lower driving portion 330 and the film fixing portion 320 may move together with the second inner driving portion 341 in the other direction of the third direction. In an embodiment, the second upper and lower driving portion 340 uses the second inner driving portion 341 and the second outer driving portion 342 as examples to drive in one direction or the other of the third direction but is not limited thereto.

The operation of the transfer film stretching device described with reference to FIGS. 7 and 8 will be described below with reference to FIGS. 10 to 20.

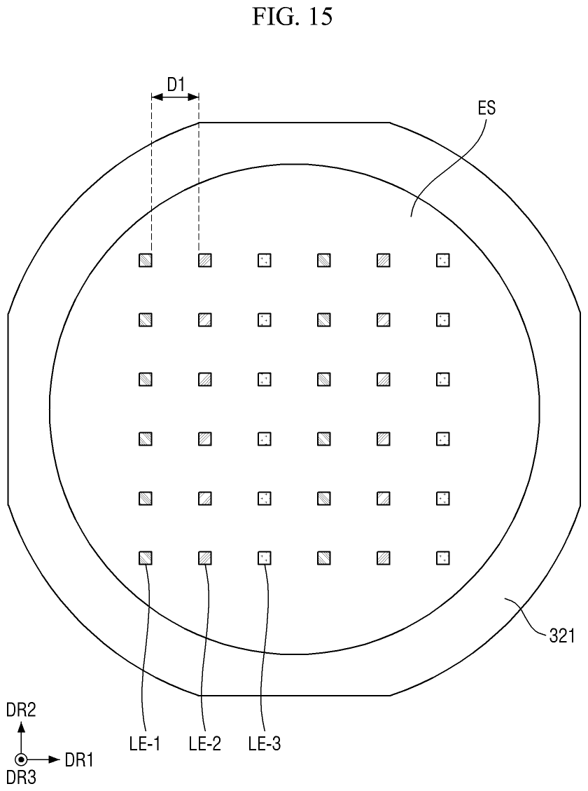

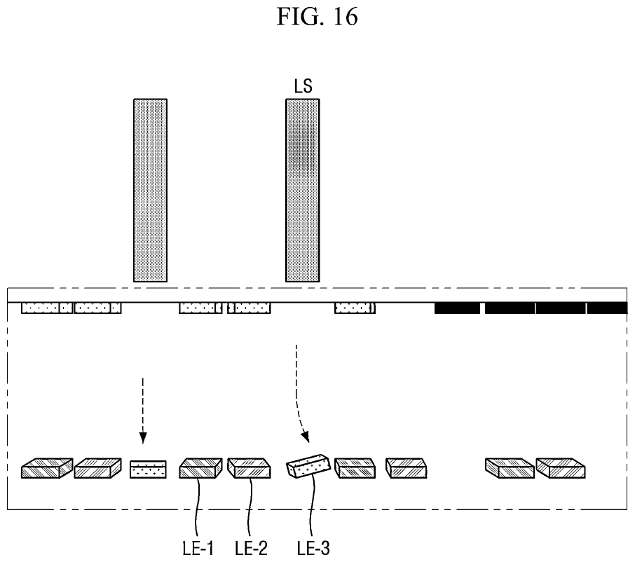

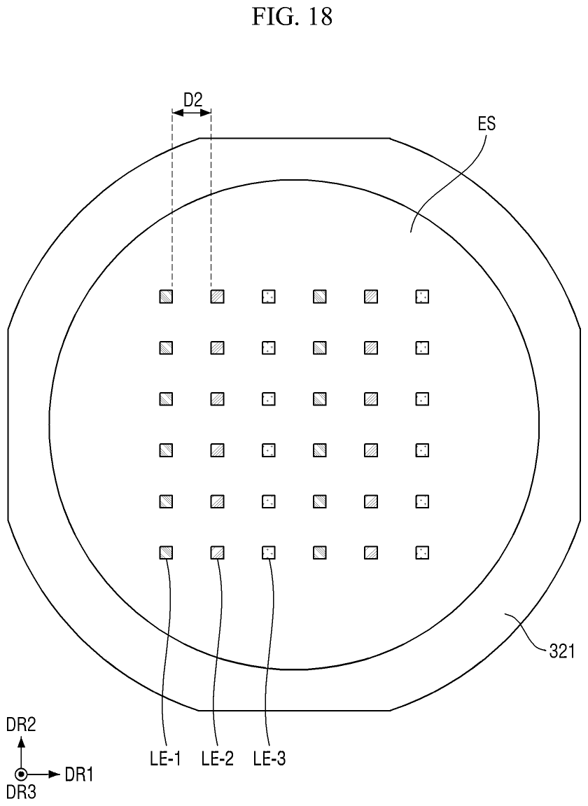

FIGS. 10 to 14, FIG. 17, FIG. 19, and FIG. 20 are schematic diagrams illustrating the operation of a transfer film stretching device according to an embodiment of the disclosure. FIGS. 15 and 18 are schematic plan views of a transfer film and a fixing frame according to an embodiment of the disclosure. FIG. 16 is a schematic diagram illustrating a laser-induced forward transfer (LIFT) process.

First, referring to FIG. 10, a transfer film stretching device 30 may move the first upper and lower driving portion 330 in the other third direction so that the pressing frame 333 presses the fixing frame 321. Accordingly, the fixing frame 321 may fix the outer periphery of the transfer film ES to the fixing bottom portion 322.

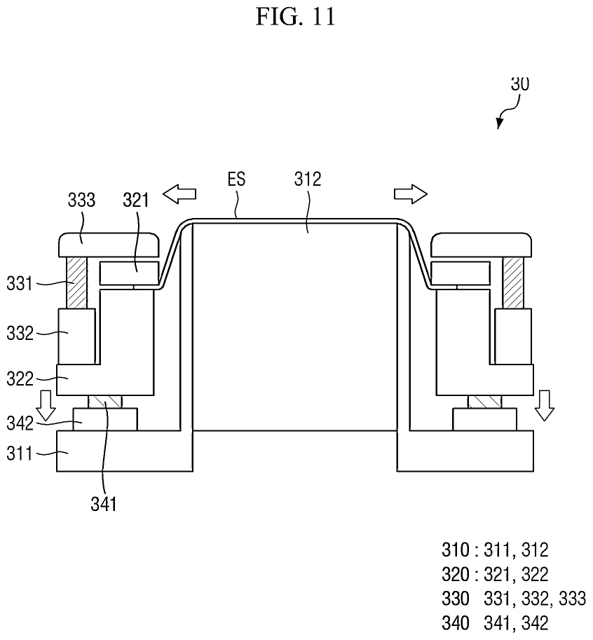

Referring to FIG. 11, the transfer film stretching device 30 may move the second upper and lower driving portion 340 in the other third direction to position the top surface of the fixing bottom portion 322 against the top surface of the support frame 311. For example, the upper surface of the fixing bottom portion 322 may positioned lower than the upper surface of the support frame 311. Accordingly, the transfer film ES fixed between the fixing bottom portion 322 and the fixing frame 321 may be pulled in the outer circumferential direction and stretched. The degree of stretching may be set and applied differently depending on the requirements of at least one of the following: the size of the transfer film ES, the diameter, the width of the arrangement of the light emitting elements LE to be transferred later or the spacing of the arrangement, and the stretching width of the transfer film ES.

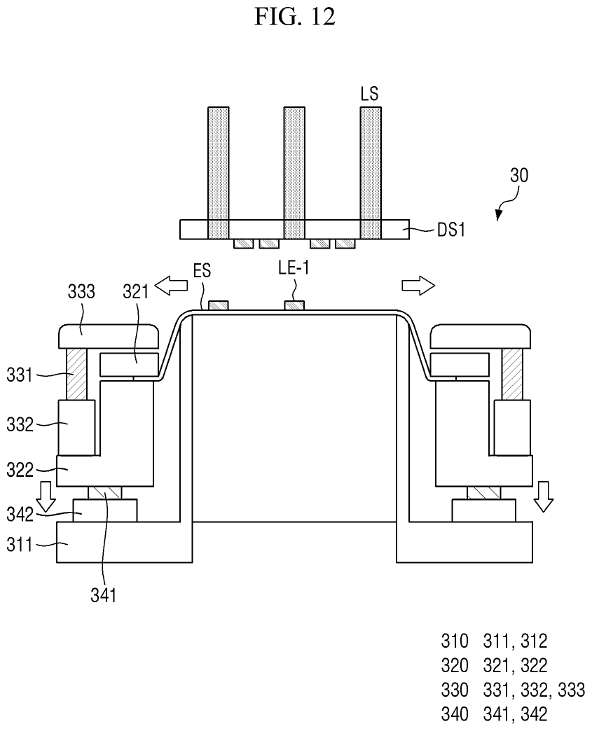

Referring to FIGS. 12 to 14, a first light emitting element LE-1, a second light emitting element LE-2, and a third light-emitting element LE-3 may emit different wavelengths of light through a laser-induced forward transfer (LIFT) process.

The LIFT process may be a non-contact material transfer technology that uses a laser to transfer a light emitting element from a donor substrate to a target substrate. The LIFT process may use, for example, a laser-induced forward transfer (LIFT) device. The LIFT device may include, for example, a telescope that parallels pulsed laser light emitted from a laser device, a structured optical system that uniformly structures the spatial intensity distribution of the pulsed laser light that has passed through the telescope, a mask that passes the pulsed laser light structured by the structured optical system in a predetermined pattern, a field lens positioned between the structured optical system and the mask, and a projection lens that shrink-projects the laser light that has passed through the pattern on the mask onto the donor substrate, thereby keeping the donor substrate on the donor stage.

As the laser device, for example, an excimer laser that oscillates laser light with a wavelength of approximately 180 nm to approximately 360 nm may be used. The oscillation wavelength of the excimer laser may be, for example, 193, 248, 308, 351 nm, etc. Among these wavelengths, any wavelength may be selected taking into account the light absorption rate of the donor substrate.

The mask may use a pattern formed by an array of windows of a predetermined size with a predetermined pitch. The mask may be patterned, for example, with chrome plating and the window portion without chrome plating transmits laser light, and the portion with chrome plating blocks the laser light.

The light emitted from the laser device may be incident on the telescopic optical system and may propagate to the structured optical system in front of it. Since the laser light just before entering the structured optical system may always be incident at approximately the same size and at the same angle (perpendicular) to the structured optical system because the telescope optics may be adjusted so that the laser light, at any position in the moving range of the X axis of the donor stage, may be approximately parallel.

The laser light that has passed through the structured optical system may be incident on the mask through the field lens, which in combination with the projection lens may constitute the image-side telecentric reduction projection optics. The laser light that has passed through the mask pattern may change its propagation direction to be vertically downward by a falling mirror and is incident on the projection lens. The laser light emitted from the projection lens may be incident from the donor substrate side and may be accurately projected to the reduced size of the mask pattern at a predetermined position of the light emitting elements arranged on the donor substrate.

The laser energy intensity in laser irradiation is not particularly limited and may be appropriately selected depending on the purpose, but is in an embodiment, approximately 5% or more and approximately 100% or less, and in another embodiment approximately 5% or more and approximately 50% or less. The laser energy intensity may be the intensity expressed as an output percentage in case that the laser irradiation intensity of 10,000 mJ/cm² is set to 100. For example, a laser energy intensity of 10% means a laser irradiation intensity of 1,000 10,000 mJ/cm².

In addition, the number of times the laser is irradiated is not particularly limited and may be appropriately selected depending on the purpose but in an embodiment is approximately 1 to approximately 10 times. The total laser irradiation intensity in laser irradiation is in an embodiment approximately 500 mJ/cm² or more and approximately 10,000 mJ/cm² or less, and in another embodiment approximately 1,000 mJ/cm² or more and approximately 5,000 mJ/cm² or less. Here, the total laser irradiation intensity is the irradiation intensity calculated as the sum of the laser irradiation intensities of the n times of laser irradiation. Here, “n” indicates the number of laser irradiation.

Referring again to FIG. 12, a first donor substrate DS1 may be disposed on the support portion 310 of the transfer film stretching device 30. A first light emitting element LE-1 that emits light of a first wavelength may be arranged on the first donor substrate DS1. The light of the first wavelength may be approximately 600 nm to approximately 750 nm, but embodiments of the specification are not limited thereto. The first light emitting element LE-1 arranged on the first donor substrate DS1 may be disposed to face the transfer film ES. Thereafter, the laser LS may be irradiated to a predetermined position of the first light emitting element LE-1 arranged on the first donor substrate DS1. Accordingly, the first light emitting element LE-1 may be separated from the first donor substrate DS1 by irradiating the laser to the first donor substrate DS1. The first light emitting element LE-1 separated from the first donor substrate DS1 may be disposed on the transfer substrate ES.

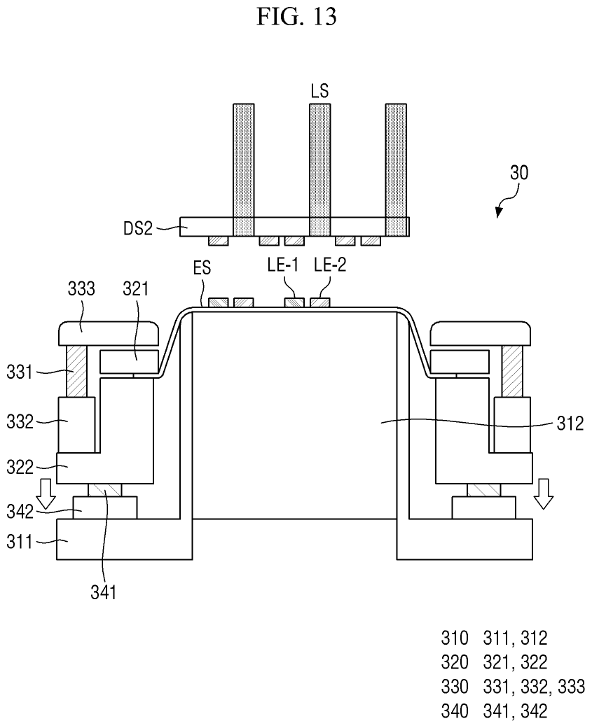

Referring to FIG. 13, a second donor substrate DS2 may be disposed on the support portion 310 of the transfer film stretching device 30. A second light emitting element LE-2 that emits light of a second wavelength may be arranged on the second donor substrate DS2. The second wavelength of light may be approximately 480 nm to approximately 560 nm, but embodiments of the specification are not limited thereto. The second light emitting element LE-2 arranged on the second donor substrate DS2 may be disposed to face the transfer film ES. Thereafter, the laser LS may be irradiated to a predetermined position of the second light emitting element LE-2 arranged on the second donor substrate DS2. Accordingly, the second light emitting element LE-2 may be separated from the second donor substrate DS2 by irradiating the laser to the second donor substrate DS2. The second light emitting element LE-2 separated from the second donor substrate DS2 may be disposed on the transfer substrate ES.

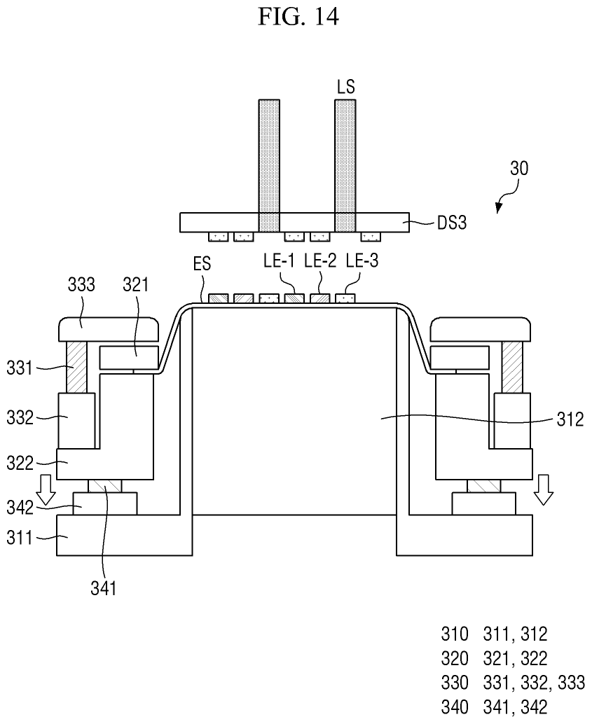

Referring to FIGS. 14 and 15, a third donor substrate DS3 may be disposed on the support portion 310 of the transfer film stretching device 30. A third light emitting element LE-3 that emits light of a third wavelength may be arranged on the third donor substrate DS3. The third wavelength of light may be approximately 370nm to approximately 460 nm, but embodiments of the specification are not limited thereto. The third light emitting element LE-3 arranged on the third donor substrate DS3 may be disposed to face the transfer film ES. Thereafter, the laser LS may be irradiated to a predetermined position of the third light emitting element LE-3 arranged on the third donor substrate DS3. Accordingly, the third light emitting element LE-3 may be separated from the third donor substrate DS3 by irradiating the laser to the third donor substrate DS3. The third light emitting element LE-3 separated from the third donor substrate DS3 may be disposed on the transfer film ES. As a result, the first light emitting element LE-1, the second light emitting element LE-2, and the third light emitting element LE-3 may be disposed on the transfer film ES in a first gap D1.

On the other hand, referring to FIG. 16, since the LIFT process may be a non-contact process as described above, if the first light emitting element LE-1, the second light emitting element LE-2, and the third light emitting element LE-3 are out of alignment at the moment of separation on the donor substrate, the alignment of the first light emitting element LE-1, the second light emitting element LE-2, and the third light emitting element LE-3 on the target substrate may be more out of alignment. Therefore, it is desirable to reduce the misalignment of the first light emitting element LE-1, the second light emitting element LE-2, and the third light emitting element LE-3 on the target substrate.

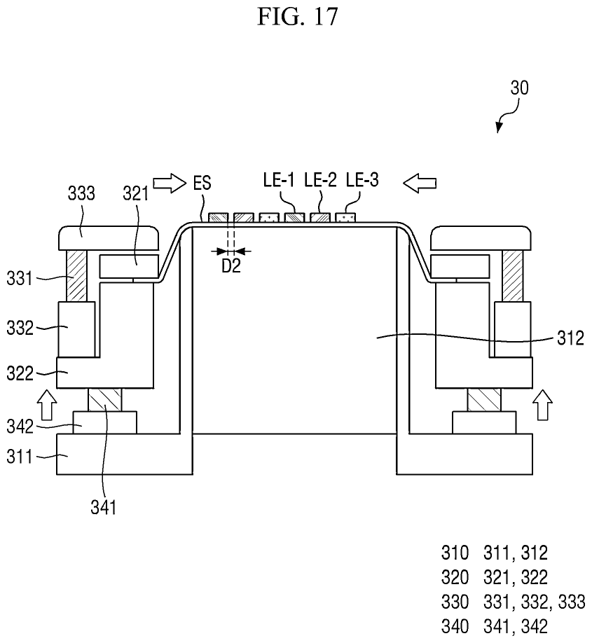

Referring to FIGS. 17 and 18, the transfer film stretching device 30 may move the second upper and lower driving portion 340 in one direction in the third direction to move the top surface of the fixing bottom portion 322 in one direction in the third direction. Thereby, the degree of stretching of the transfer film ES fixed between the fixing bottom portion 322 and the fixing frame 321 may be reduced. Thus, the first light emitting element LE-1, the second light emitting element LE-2, and the third light emitting element LE-3 may be disposed on the transfer film ES in the second gap D2. It can be seen that the second gap D2 is narrower than the first gap D1.

Compared to the separation distance between the first light emitting element LE-1, the second light emitting element LE-2, and the third light emitting element LE-3 in FIG. 15, it can be seen that the separation distance of the first light emitting element LE-1, the second light emitting element LE-2, and the third light emitting element LE-3 in FIG. 18 is narrowed. As such, in case that the degree of stretching of the transfer film ES is reduced, the possible position error of the first light emitting element LE-1, the second light emitting element LE-2, and the third light emitting element LE-3 may also be reduced. Here, the position error may mean the error between the target position where the light emitting element is to be placed and a position where the light emitting element is placed. If the possible position error of the first light emitting element LE-1, the second light emitting element LE-2, and the third light emitting element LE-3 is reduced, product quality may be improved, and yield may be increased by reducing product defects.

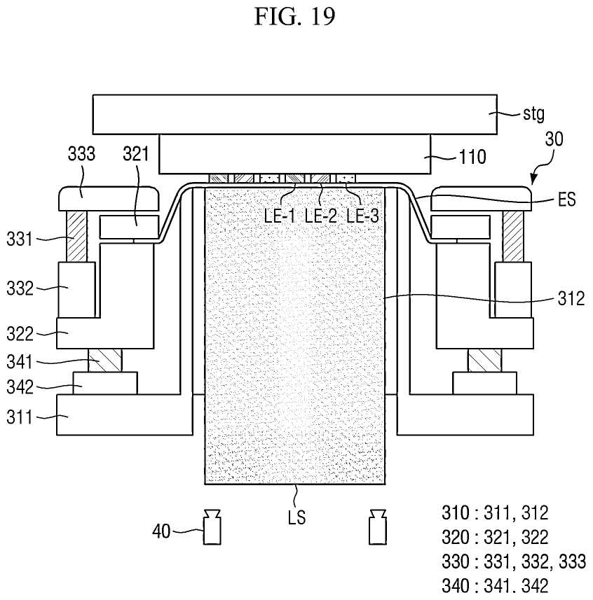

Referring to FIG. 19, the substrate 110 may be placed on the support portion 310 of the transfer film stretching device 30. The first to third light emitting elements LE-1, LE-2, and LE-3 disposed on the transfer film ES may be transferred onto the substrate 110. At this time, the transfer film ES may become the donor substrate and the substrate 110 may become the target substrate.

For example, the substrate 110 may be placed in contact with the light emitting elements LE arranged on the transfer film ES. The connection electrode 150 described with reference to FIGS. 4 and 5 may be disposed on the top surfaces of the first to third light emitting elements LE-1, LE-2, and LE-3. Accordingly, the connection electrode 150 may directly contact the substrate 110.

Subsequently, the laser light may be applied to the back side of the laser transmitting portion 312 in the front direction. Accordingly, the laser may pass through the transfer film ES and be emitted to the connection electrode 150. The connection electrode 150 may be melted so that the first to third light emitting elements LE-1, LE-2, and LE-3 and the substrate 110 may be melt-bonded. A support member Stg supporting the substrate 110 may press the substrate 110 during melt bonding to contribute to the bonding between the first to third light emitting elements LE-1, LE-2, and LE-3 and the substrate 110.

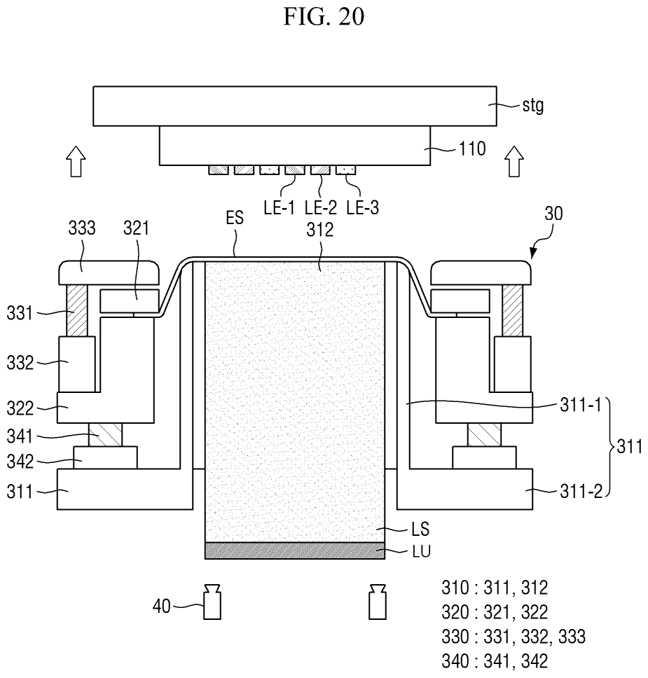

Referring to FIG. 20, the support member Stg may be lifted in one direction of the third direction. The first to third light emitting elements LE-1, LE-2, and LE-3 may be melt-bonded to the substrate 110 and lifted together with the substrate 110. As a result, the first to third light emitting elements LE-1, LE-2, and LE-3 on the transfer film ES may be transferred to the substrate 110.

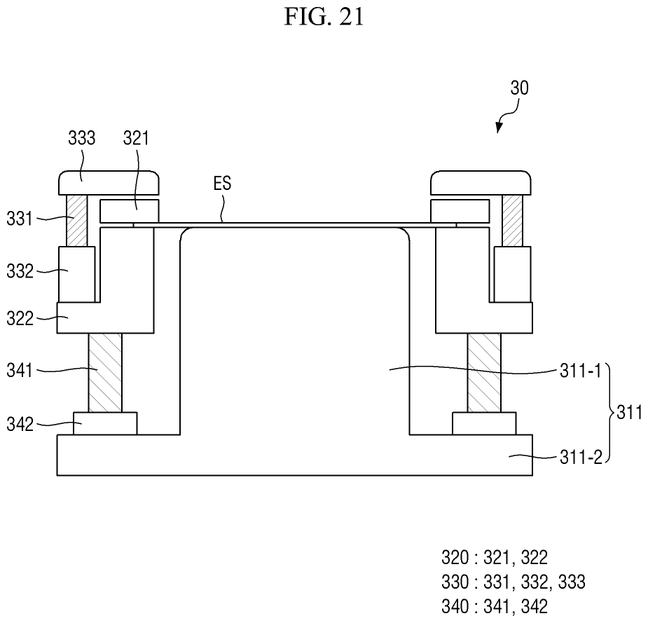

FIG. 21 is a schematic diagram illustrating the structure of a transfer film stretching device according to another embodiment of the disclosure.

The transfer film stretching device described with reference to FIG. 21 may differ from the structure of the transfer film stretching device described with reference to FIGS. 7 and 8 at least in that the support portion 310 may not include the laser transmitting portion 312. Hereinafter, descriptions overlapping with the above-described embodiment will be omitted and differences will be described.

Referring to FIG. 21, the support portion 310 of the transfer film stretching device may support the transfer film ES while stretching the entire width of the transfer film ES in the outer peripheral direction.

The support portion 310 may include a center portion 311-1 and a side portion 311-2.

The center portion 311-1 and the side portion 311-2 may have a cylindrical shape. The diameter of the side portion 311-2 may be larger than the diameter of the center portion 311-1. The height of the side portion 311-2 may be lower than the height of the center portion 311-1. The side portion 311-2 may surround the center portion 311-2 at the bottom end of the center portion 311-1.

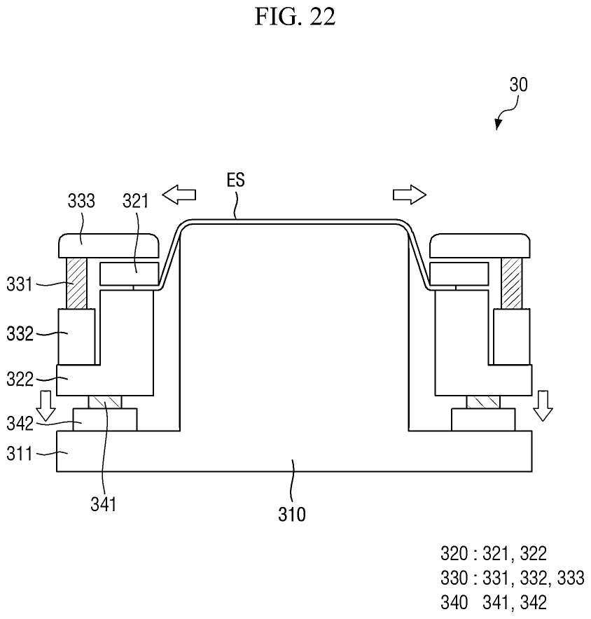

The operation of the transfer film stretching device described with reference to FIG. 21 will be described below with reference to FIGS. 22 to 27.

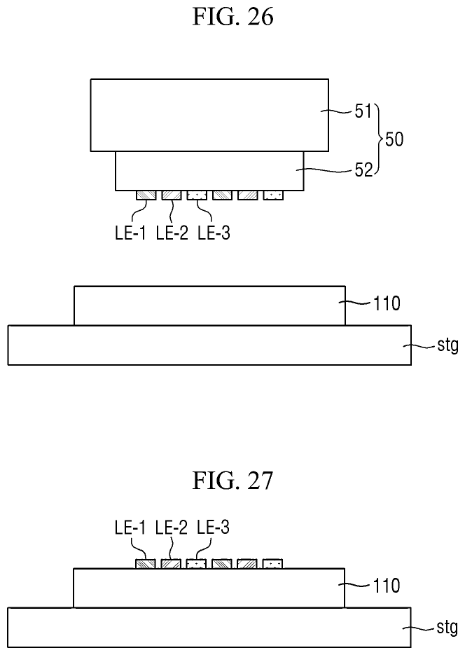

FIGS. 22 to 25 are schematic diagrams illustrating the operation of a transfer film stretching device according to another embodiment of the disclosure. FIGS. 26 and 27 are schematic diagrams illustrating a method of placing light emitting elements on a substrate using a transfer head according to an embodiment of the disclosure.

Referring to FIG. 22, the transfer film stretching device 30 moves the second upper and lower driving portion 340 in the other direction of the third direction to position the top surface of the fixing bottom portion 322 against the top surface of the support frame 311. For example, the upper surface of the fixing bottom portion 322 is positioned lower than the upper surface of the support frame 311. Accordingly, the transfer film ES fixed between the fixing bottom portion 322 and the fixing frame 321 is pulled in the outer circumferential direction and stretched.

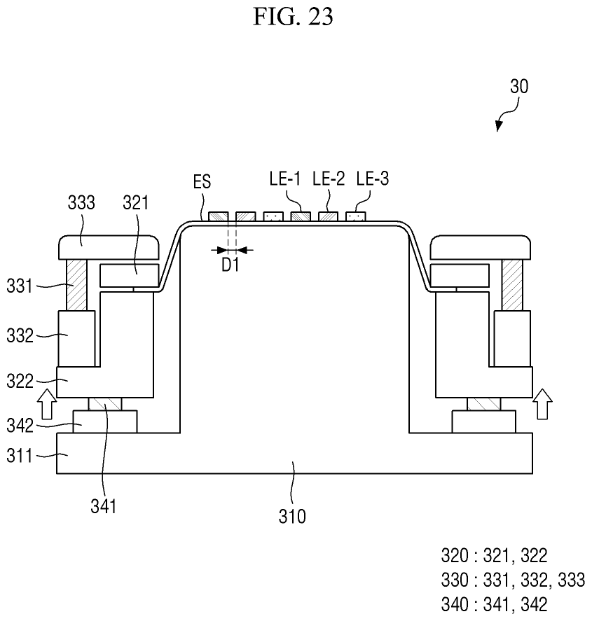

Referring to FIG. 23, the first light emitting element LE-1, the second light emitting element LE-2, and the third light emitting element LE-3 on the donor substrate are transferred onto the transfer film ES by the LIFT process. Since the LIFT process has been described with reference to FIGS. 12 to 14, redundant description will be omitted. At this time, the first light emitting element LE-1, the second light emitting element LE-2, and the third light emitting element LE-3 may be light emitting elements that emit light of different wavelengths. The first light emitting element LE-1, the second light emitting element LE-2, and the third light emitting element LE-3 may be arranged to be spaced apart from each other at a first gap D1.

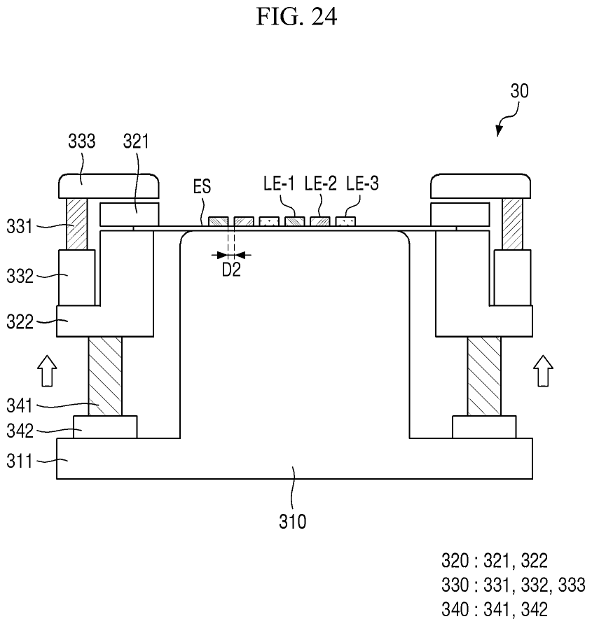

Referring to FIG. 24, the transfer film stretching device 30 moves the second upper and lower driving portion 340 in one direction in the third direction to move the top surface of the fixing bottom portion 322 in one direction in the third direction. Thereby, the degree of stretching of the transfer film ES fixed between the fixing bottom portion 322 and the fixing frame 321 may be reduced. Thus, the first light emitting element LE-1, the second light emitting element LE-2, and the third light emitting element LE-3 may be disposed on the transfer film ES in the second gap D2. It can be seen that the second gap D2 is narrower than the first gap D1.

Referring to 25 to 27, a transfer device 50 is used to transfer the first light emitting element LE-1, the second light emitting element LE-2, and the third light emitting element LE-3 arranged on the transfer film ES onto the substrate 110.

The transfer device 50 may include a transfer rail, a transfer head 51 and a stamp 52.

The transfer head 51 may be installed to be movable on a transfer rail. The transfer rail may be disposed between the transfer film stretching device 30 and the substrate 110.

The stamp 52 is attached to the transfer head 51 and includes a viscous member at one end. The viscous member may include, for example, an acrylic, urethane, or silicone adhesive material but is not limited thereto. The adhesiveness of the viscous member may change significantly depending on heat or temperature. As a result, the first light emitting element LE-1, second light emitting element LE-2, and third light emitting element LE-3 may be attached to or detached from the stamp 52. In an embodiment, one side of the stamp 52 is formed flat, but embodiments are not limited to this configuration, and one side of the stamp 52 may have a protrusion. In case that protrusions are formed on the stamp 52, a light emitting element may be adhered to each protrusion of the stamp 52 in a one-to-one manner.

For example, the transfer device 50 is located on the transfer film ES. The transfer device 50 is moved to the other side in the third direction to contact the first light emitting element LE-1, the second light emitting element LE-2, and the third light emitting element LE-3 arranged on the transfer film ES with the stamp 52. The first light emitting element LE-1, the second light emitting element LE-2, and the third light emitting element LE-3 may adhere to the stamp 52 due to the viscous member of the stamp 52.

The transfer device 50 moves to one side in the third direction and moves to at least one of the first direction and the second direction to be positioned on the substrate 110. The transfer device 50 is located on the substrate 110 and moves to the other side in the third direction to place the first light emitting element LE-1, the second light emitting element LE-2, and the third light emitting element LE-3 on the substrate 110. A device such as a laser applies heat to the viscous member to detach the first light emitting element LE-1, the second light emitting element LE-2, and the third light emitting element LE-3 from the stamp 52. Thereafter, a device such as a laser may pressurize and melt bond the first light emitting element LE-1, the second light emitting element LE-2, and the third light emitting element LE-3 onto the substrate 110.

In the steps of FIGS. 26 and 27, the first light emitting element LE-1, the second light emitting element LE-2, and the third light emitting element LE-3 may be disposed on the substrate 110 with the second gap D2 of the first light emitting element LE-1, the second light emitting element LE-2, and the third light emitting element LE-3 disposed on the transfer substrate ES. That is, it can be seen that the first light emitting element LE-1, the second light emitting element LE-2, and the third light emitting element LE-3 on the substrate 110 are transferred to the substrate 110 at the second gap D2.

In this way, the position error of the light emitting elements that may occur during the lift process may be reduced by overstretching the transfer film using the transfer film stretching device according to some embodiments and reducing the degree of stretching after placing the light emitting elements.

However, the aspects of the disclosure are not restricted to the one set forth herein. The above and other aspects of the disclosure will become more apparent to one of daily skill in the art to which the disclosure pertains by referencing the claims, with functional equivalents thereof to be included therein.

What is claimed is:

1. A method of transferring a plurality of light emitting elements using a stretching device, comprising:
stretching a transfer film disposed on a support portion of the stretching device by a stretching portion;
disposing the plurality of light emitting elements at a first gap on the transfer film;
reducing an elongation of the transfer film so that the stretching portion disposes the plurality of light emitting elements at a second gap narrower than the first gap; and
transferring the plurality of light emitting elements disposed at the second gap on the transfer film to a substrate.

2. The method of claim 1, wherein the disposing of the plurality of light emitting elements at the first gap on the transfer film comprises:
disposing a first light emitting element emitting light of a first wavelength on the transfer film;
disposing a second light emitting element emitting light of a second wavelength on the transfer film; and
disposing a third light emitting element emitting light of a third wavelength on the transfer film.

3. The method of claim 2, wherein disposing the plurality of light emitting elements at the first gap on the transfer film comprises:
moving the plurality of light emitting elements from a donor substrate to the transfer film by a laser-induced forward transfer (LIFT) process.

4. The method of claim 1, wherein the stretching of the transfer film disposed on the support portion comprises:
moving a film fixing portion in a direction to place a height of the film fixing portion lower than a height of a top surface of the support portion after fixing an outer periphery of the transfer film by the film fixing portion of the stretching portion.

5. The method of claim 4, wherein the reducing of the elongation of the transfer film so that the stretching portion disposes the plurality of light emitting elements at the second gap narrower than the first gap comprises:
the stretching portion moving the film fixing portion in the direction to reduce a difference between a height of the film fixing portion and a height of the top surface of the support portion.

6. The method of claim 1, wherein the transferring of the plurality of light emitting elements disposed at the second gap on the transfer film to the substrate comprises,
disposing the substrate on the transfer film on which the plurality of light emitting elements disposed at the second gap are disposed;
contacting the substrate with upper portions of the plurality of light emitting elements; and
irradiating a laser from a lower portion of the support portion to the transfer film.

7. The method of claim 6, wherein the support portion has an opening in a center, and a laser transmitting member is disposed in the opening, the method further comprising:
irradiating a laser from a lower portion of the support portion to the transfer film; and
irradiating the laser to melt a connection electrode disposed on a top surface of the plurality of light emitting elements and adhering the plurality of light emitting elements to the substrate.

8. The method of claim 6, wherein the irradiating of the laser from the lower portion of the support portion to the transfer film comprises:
confirming an alignment of the plurality of light emitting elements and the substrate by an image captured by a vision member disposed at a lower end of the support portion and photographing the plurality of light emitting elements.

9. The method of claim 1, wherein the transferring of the plurality of light emitting elements disposed at the second gap on the transfer film to the substrate comprises:
disposing a transfer head on the transfer film on which the plurality of light emitting elements disposed at the second gap are disposed;
moving the transfer head to adhere the plurality of light emitting elements to a stamp of the transfer head;
moving the transfer head to place the plurality of light emitting elements adhered to the stamp on the substrate; and
melting bonding a connection electrode disposed at an end of the plurality of light emitting elements to the substrate.

10. The method of claim 9, wherein the moving of the transfer head to adhere the plurality of light emitting elements to the stamp of the transfer head comprises:
attaching a viscous member disposed on a side of the stamp to the plurality of light emitting elements.

11. The method of claim 2, wherein the plurality of light emitting elements are at least one of vertical light emitting elements and flip-chip light emitting elements.

12. A method of transferring a plurality of light emitting elements using a stretching device, comprising:
disposing the plurality of light emitting elements at a first gap on a transfer film that is stretched;
disposing a stretching portion to space the plurality of light emitting elements at a second gap narrower than the first gap;
disposing a substrate on the transfer film on which the plurality of light emitting elements at the second gap are disposed;
contacting the substrate with a top surface of the plurality of light emitting elements;
bonding the plurality of light emitting elements to the substrate by irradiating a laser from a bottom surface of the transfer film toward the plurality of light emitting elements and separating the transfer film and the plurality of light emitting elements.

13. The method of claim 12, further comprising:
before disposing the plurality of light emitting elements at the first gap on the transfer film that is stretched:
disposing the transfer film on a support; and
moving the stretching portion of the stretching device in a direction to stretch the transfer film disposed on a support portion.

14. The method of claim 13, wherein the support portion has an opening in a center, and a laser transmitting member is disposed in the opening, the method further comprising:
bonding the plurality of light emitting elements to the substrate by irradiating the laser from a lower portion of the support portion to the transfer film and separating the transfer film and the plurality of light emitting elements; and
irradiating the laser to melt a connection electrode disposed on the top surface of the light emitting elements and adhering the plurality of light emitting elements to the substrate.

15. The method of claim 12, wherein the disposing of the plurality of light emitting elements at the first gap on the transfer film that is stretched comprises:
disposing a first light emitting element emitting light of a first wavelength on the transfer film;
disposing a second light emitting element emitting light of a second wavelength on the transfer film; and
disposing a second light emitting element emitting light of a third wavelength on the transfer film.

16. The method of claim 15, wherein the disposing of the plurality of light emitting elements at the first gap on the transfer film comprises:
moving the plurality of light emitting elements from a donor substrate to the transfer film by a laser-induced forward transfer (LIFT) process.

17. The method of claim 13, wherein the stretching portion comprises:
a fixing frame having a circular or polygonal panel or frame structure with a circular or polygonal opening; and
a film fixing portion including the fixing frame and a lower fixing portion disposed below an upper and lower driving portion.

18. The method of claim 17, wherein the moving of the stretching portion of the stretching device in the direction to stretch the transfer film disposed on the support portion comprises:
fixing an outer periphery of the transfer film by the film fixing portion and disposing a height of the film fixing portion to be lower than a height of a top surface of the support portion.

19. The method of claim 14, wherein the bonding of the plurality of light emitting elements to the substrate by irradiating the laser from the lower portion of the support portion to the transfer film comprises:
confirming an alignment of a plurality of light emitting elements and the substrate by an image captured by a vision member disposed at a lower end of the support portion and photographing the plurality of light emitting elements.

20. The method of claim 14, wherein the plurality of light emitting elements are at least one of vertical light emitting elements or flip-chip light emitting elements.
